(19) United States
(12) Patent Application Publication
(10) Pub. No.: US 2006/0203873 A1
(43) Pub. Date: Sep. 14, 2006

(54) Semiconductor laser diode

(76) Inventors: Xin Gao, Shizuoka (JP); Yujin Zheng, Shizuoka (JP)

Correspondence Address: DRINKER BIDDLE & REATH (DC), 1500 K STREET, N.W., SUITE 1100, WASHINGTON, DC, 20005-1209, US

(21) Appl. No.: 10/566,265

(22) PCT Filed: May 7, 2004
(86) PCT No.: PCT/JP04/06501

§ 371 Date: Jan. 30, 2006

(30) Foreign Application Priority Data
Jul. 31, 2003 (JP) 2003-284130
Jan. 28, 2004 (JP) 2004-020337

(51) Int. Cl. H01S 5/00

(52) U.S. Cl. 372/50.12

(57) ABSTRACT

The present invention relates to a semiconductor laser device having a structure capable of emitting laser beam having a small spread angle and further of narrowing the spectrum width of the laser beam. The semiconductor laser device comprises a semiconductor laser array, a collimator lens, and an optical element having at least partially a reflecting function. The semiconductor laser array has plural active layers, and the active layers extend along a first direction on a predetermined plane and are arranged in parallel along a second direction perpendicular to the first direction on the predetermined plane. The collimator lens collimates plural beams, respectively emitted from the active layers, in a third direction perpendicular to the predetermined plane. Then, the optical element has a reflecting portion for reflecting part of each beam reaching from the collimator lens and a transmitting portion for transmitting the rest of the reaching beam on a plane facing the collimator lens, so as to constitute an off-axis external resonator having a resonant optical path deviated from the optical axis of each beam emitted from the collimator lens and having a predetermined spread angle in the second direction together with the active layers.

### TECHNICAL FIELD

The present invention relates to a semiconductor laser device having plural laser beam sources.

### BACKGROUND ART

There has conventionally been known a semiconductor laser device comprising: a semiconductor laser array having plural active layers which are arranged in parallel along a predetermined direction; a collimator lens for collimating plural beams emitted from the active layers in the direction perpendicular to the arrangement direction of the active layers; and an optical path converting element for receiving the beams collimated by the collimator lens and for rotating the cross-section of each of the beams by approximately 90° (refer to Reference 1: Japanese Patent Gazette No. 3071360, for example).

FIGS. 1A and 1B are views illustrating a spread angle of a beam emitted from each active layer 103 of the semiconductor layer array 101 in the semiconductor laser device described in Reference 1, where FIG. 1A is a side elevational view showing the spread angle of a beam, while FIG. 1B is a plan view also showing the spread angle of the beam. In addition, the coordinate axes (x-axis, y-axis, and z-axis) are set in such a manner that the laser beam emitting direction of the semiconductor laser array is represented by the x-axis, that the arrangement direction of the active layers is represented by the y-axis, and that the direction perpendicular to both the x-axis and y-axis directions is represented by the z-axis. The spread angle of a beam emitted from each active layer is 30° to 40° in the z-axis direction centering on the optical axis 105 (FIG. 1A), while 8° to 10° in the y-axis direction (FIG. 1B). In the semiconductor laser device described in Reference 1, the collimator lens collimates beams in the vertical direction, and then the optical path converting element rotates the cross-section of each of the beams by 90°, whereby there is achieved a structure in which adjacent beams are not likely to intersect with each other.

### DISCLOSURE OF THE INVENTION

The inventors have studied conventional semiconductor laser devices in detail, and as a result, have found problems as follows. That is, in view of various kinds of applications, laser beams emitted from a laser device are required to have a small spread angle as well as a narrow spectrum width in general.

However, since the semiconductor laser device described in Reference 1 only rotates the cross-section of each of the beams by 90° using the optical path converting element, the spread angle in the y-axis direction corresponds to that in the z-axis direction as it is. Laser beams emitted finally from the semiconductor laser device still have a spread angle of 8° to 10° in the z-axis direction. Also, in the semiconductor laser device described in Reference 1, since the beam emitted from each active layer 103 in the semiconductor laser array 101 has a large spectrum width, laser beams emitted finally from the semiconductor laser device also have a large spectrum width.

The present invention has been made to solve the above-described problems, and an object thereof is to provide a semiconductor laser device having a structure capable of emitting a laser beam having a small spread angle and further of narrowing the spectrum width of the laser beam.

In order to achieve the foregoing object, a semiconductor laser device according to the present invention comprises at least one of a semiconductor laser array and a semiconductor laser array stack, a collimator lens, and an optical element. The semiconductor laser array has plural active layers that extend along a first direction on a predetermined plane and that are arranged in parallel along a second direction perpendicular to the first direction on the predetermined plane. Also, the semiconductor laser array stack has a structure in which plural semiconductor laser arrays are stacked in a third direction perpendicular to a predetermined plane, the semiconductor laser arrays respectively having plural active layers that extend along a first direction on the predetermined plane and that are arranged in parallel along a second direction perpendicular to the first direction on the predetermined plane. The collimator lens collimates plural beams, respectively emitted from the active layers, in the third direction perpendicular to the predetermined plane. Then, the optical element is arranged at a position where at least part of each beam emitted from the collimator lens and having a predetermined spread angle in the second direction reaches, in an inclined manner with respect to a plane perpendicular to the first direction. The optical element also has, on a plane facing the collimator lens, a reflecting portion for reflecting part of each beam reaching from the collimator lens and a transmitting portion for transmitting the rest of the reaching beam.

In the above-described arrangement, the optical element is preferably arranged in such a manner that part of each beam reaching the reflecting portion from the collimator lens is fedback to the active layers. In this case, between the optical element and the active layers is formed an off-axis external resonator having a resonant optical path (specifically, an optical path routed through the rear end surface facing the laser beam emitting end surface of the active layers between the reflecting surface of the optical element and the laser beam emitting end surface of the active layers) deviated from the optical axis of each beam.

In the semiconductor laser device according to the present invention, beams emitted from the active layers of the semiconductor laser array, which spread in the vertical (third) direction from the active layers, are refracted through the collimator lens to be in approximately parallel in the vertical direction to reach the optical element. Since at least part of beam reflected at the reflecting portion, among beams reaching the optical element, is fedback to the active layer that has emitted the beam, the above arrangement constitutes an external resonator and causes stimulated emission in the active layers to achieve laser oscillation. Meanwhile, beam that transmits through the transmitting portion of the optical element is emitted outside the optical element.

In the semiconductor laser device according to the present invention, the borderline between the reflecting portion and the transmitting portion of the optical element may be parallel to or perpendicular to the second direction. In the latter case, the optical element preferably provides the reflecting portion and the transmitting portion alternately along the second direction.

Also, in the semiconductor laser device according to the present invention, the optical element preferably comprises a tabular substrate comprised of translucent material, which is transparent to beam emitted from the active layers, and having a surface on which the reflecting portion and the transmitting portion formed alternately along the longitudinal direction. In this case, since the optical element itself is integrated, it is easy to handle the optical element and thereby to assemble the semiconductor laser device and adjust the optical axis thereof.

In the semiconductor laser device according to the present invention, the translucent substrate of the optical element is preferably arranged in an inclined manner with respect to a plane perpendicular to the optical axis of each beam, emitted from the collimator lens and having a spread angle in the second direction, so that at least part of each beam reaching the reflecting portion enters the reflecting portion perpendicularly. In this case, part of each beam emitted from the collimator lens in a spreading manner in the second direction enters the reflecting portion perpendicularly, and then follows the incident path reversely to be fedback to the active layers. The above arrangement constitutes an external resonator to achieve highly efficient laser oscillation.

In addition, each reflecting portion of the optical element includes a total reflection film, a diffraction grating, or an etalon formed on the surface of the translucent substrate. Meanwhile, each transmitting portion may include a reflection suppressing film formed on the surface of the translucent substrate.

Further, the semiconductor laser device according to the present invention may comprise one of a semiconductor laser array and a semiconductor laser array stack, a collimator lens, an optical element partially having a reflecting function, and a wavelength selecting element. In particular, the wavelength selecting element is arranged in such a manner that part of each beam, emitted from the collimator lens and having a spread angle in the second direction, reaches perpendicularly, and constitutes an off-axis external resonator having a resonant optical path deviated from the optical axis of each beam together with the optical element. The wavelength selecting element also Bragg-reflects part of beam with a specific wavelength, among the perpendicularly reaching beams, in such a manner as to be fedback to the active layers, while transmitting the rest of the beam with the specific wavelength.

In the thus arranged semiconductor laser device, beams, which are emitted from the active layers of the semiconductor laser array and which spread in the vertical (third) direction from the respective active layers, are refracted by the collimator lens to be approximately parallel in the vertical direction to enter the optical element or the wavelength selecting element. In the optical element, at least part of each beam reflected at the reflecting portion is fedback to the active layer that has emitted the beam. Alternatively, part of beam with a specific wavelength is Bragg-reflected by the wavelength selecting element, among the beams that enter the wavelength selecting element, and at least part of the reflected beam is fedback to the active layer that has emitted the beam. The above arrangement constitutes an external resonator between the reflecting portion of the optical element and the wavelength selecting element, and causes stimulated emission in active layers positioned within the resonator to achieve laser oscillation. Meanwhile, beam that transmits through the transmitting portion of the optical element is emitted outside as output of the semiconductor laser device.

In addition, the semiconductor laser device according to the present invention may comprise a wavelength selecting element for diffracting and reflecting beams diffractively instead of such a wavelength selecting element as mentioned above for causing Bragg reflection. That is, the wavelength selecting element is arranged in such a manner that part of each beam, emitted from the collimator lens and having a spread angle in the second direction, is reflected diffractively, and constitutes an off-axis external resonator having a resonant optical path deviated from the optical axis of each beam together with the optical element. Such a wavelength selecting element reflects diffractively diffracted beam with a specific wavelength of a specific order, among diffracted beams, in such a manner as to be fedback to the active layers, while guiding diffracted beam with the specific wavelength of an order other than the specific order outside.

In the thus arranged semiconductor laser device, beams, which are emitted from the respective active layers of the semiconductor laser array and which spread in the vertical (third) direction from the active layers, are refracted by the collimator lens to be parallel in the vertical direction to enter the optical element. In the optical element, at least part of each beam reflected at the reflecting portion is fedback to the active layer that has emitted the beam. Also, beam that transmits through the transmitting portion of the optical element enters the wavelength selecting element that can reflect the beam diffractively. Beam with a specific wavelength of a specific diffraction order, among the beams that enter the wavelength selecting element, is fedback to the active layer that has emitted the beam. The above arrangement constitutes an external resonator between the reflecting portion of the optical element and the wavelength selecting element, and causes stimulated emission in active layers positioned within the resonator to achieve laser oscillation. Meanwhile, diffracted beam with the specific wavelength of an order other than the specific diffraction order, among the beams that enter the wavelength selecting element, is emitted outside as output of the semiconductor laser device.

In the semiconductor laser device according to the present invention, the optical element is preferably arranged between the collimator lens and the wavelength selecting element, and the wavelength selecting element is preferably arranged at a position where each beam, entering the transmitting portion of the optical element from the collimator lens and transmitting through the transmitting portion, reaches. Alternatively, the wavelength selecting element for causing Bragg reflection may be provided between the collimator lens and the optical element, and arranged in the optical path of each beam that propagates from the collimator lens to the transmitting portion of the optical element. Any one of these cases constitutes an external resonator between the reflecting portion of the optical element and the wavelength selecting element, and causes stimulated emission in active layers positioned within the resonator to achieve laser oscillation.

The optical element may be arranged in such a manner that a reflecting mirror simply constitutes the reflecting portion and that no medium is provided as the transmitting portion. In this case, the reflecting mirror is arranged in such a manner as to reflect part of each beam reaching from the collimator lens, and the rest of the beam enters the wavelength selecting element.

The optical element preferably comprises a tabular substrate comprised of translucent material which is transparent to beam emitted from the active layers and having a surface on which the reflecting portion and the transmitting portion formed. In this case, since the optical element itself is integrated, it is easy to handle the optical element and thereby to assemble the semiconductor laser device and adjust the optical axis thereof.

The optical element is preferably arranged in such a manner that the reflecting portion and the transmitting portion are arranged alternately along the second direction (the direction in which plural active layers are arranged in the semiconductor laser array).

Further, the optical element is preferably arranged such that the beam enters the reflecting portion perpendicularly, while the reflecting portion is inclined with respect to a plane perpendicular to the optical axis of each beam emitted from the collimator lens. In this case, part of each beam emitted from the collimator lens in a spreading manner in the second direction enters the reflecting portion perpendicularly, and then follows the incident path reversely to be fedback to the active layers. The above arrangement constitutes an external resonator to achieve highly efficient laser oscillation.

Also, in the semiconductor laser device according to the present invention, the wavelength selecting element may be arranged at a position where part of each beam, emitted from the collimator lens and having a spread angle in the second direction, reaches via the optical element. In this case, the wavelength selecting element causes the reached beam to be fedback to the active layers via the optical element.

To be more concrete, the wavelength selecting element may be arranged at a position where part of each beam reflected by the reflecting portion of the optical element, among beams emitted from the collimator lens and having a spread angle in the second direction, reaches. In this case, the reached beam is fedback to the active layers via the reflecting portion. Meanwhile, the wavelength selecting element may be arranged at a position where part of each beam transmitting through the transmitting portion of the optical element, among beams emitted from the collimator lens and having a spread angle in the second direction, reaches. In this case, the beam reaching the wavelength selecting element is fedback to the active layers through the transmitting portion. The above arrangement constitutes an off-axis external resonator having a resonant optical path deviated from the optical axis of each beam between the active layers and the wavelength selecting element.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the spirit and scope of the invention will be apparent to those skilled in the art from this detailed description.

### BRIEF DESCRIPTION OF THE DRAWINGS

FIG. 1A is a side elevational view illustrating the spread angle of a beam emitted from active layers of a semiconductor laser array, while FIG. 1B is a plan view thereof;

FIG. 2A is a plan view showing the configuration of a first embodiment of a semiconductor laser device according to the present invention, while FIG. 2B is a side elevational view thereof;

FIG. 3 is a perspective view showing a semiconductor laser array and a beam emitted from the semiconductor laser array;

FIG. 4A is a view showing the front end surface (beam emitting surface) of the semiconductor laser array, while FIG. 4B is a view showing the front end surface of an active layer;

FIG. 5 shows a horizontal (in the y-axis direction) optical intensity distribution of an output from a semiconductor laser array to be applied to the semiconductor laser device according to the first embodiment;

FIG. 6 is a perspective view showing the configuration of a collimator lens to be applied to the semiconductor laser device according to the first embodiment;

FIG. 7 is a perspective view showing the configuration of an optical element to be applied to the semiconductor laser device according to the first embodiment;

FIG. 8A shows cross-sections (emitting patterns) of beams generated in active layers before entering the collimator lens, while FIG. 8B shows cross-sections of the beams after passing through the collimator lens;

FIG. 9 shows a horizontal (in the y-axis direction) optical intensity distribution of a beam emitted from semiconductor laser device according to the first embodiment;

FIG. 10A is a plan view showing the configuration of a second embodiment of a semiconductor laser device according to the present invention, while FIG. 10B is a side elevational view thereof;

FIG. 11 is a perspective view showing the configuration of a semiconductor laser array stack;

FIG. 12A is a plan view showing the configuration of a third embodiment of a semiconductor laser device according to the present invention, while FIG. 12B is a side elevational view thereof;

FIG. 13 is a perspective view showing the configuration of an optical element to be applied to the semiconductor laser device according to the third embodiment;

FIG. 14A is a plan view showing the configuration of a fourth embodiment of a semiconductor laser device according to the present invention, while FIG. 14B is a side elevational view thereof;

FIG. 15 is a perspective view showing the configuration of a wavelength selecting element to be applied to the semiconductor laser device according to the fourth embodiment;

FIG. 16A is a plan view showing the configuration of a fifth embodiment of a semiconductor laser device according to the present invention, while FIG. 16B is a side elevational view thereof;

FIG. 17A is a plan view showing the configuration of a sixth embodiment of a semiconductor laser device according to the present invention, while FIG. 17B is a side elevational view thereof;

FIG. 18A is a plan view showing the configuration of a seventh embodiment of a semiconductor laser device according to the present invention, while FIG. 18B is a side elevational view thereof;

FIG. 19A is a plan view showing the configuration of an eighth embodiment of a semiconductor laser device according to the present invention, while FIG. 19B is a side elevational view thereof;

FIG. 20A is a plan view showing the configuration of a ninth embodiment of a semiconductor laser device according to the present invention, while FIG. 20B is a side elevational view thereof;

FIG. 21A is a plan view showing the configuration of a tenth embodiment of a semiconductor laser device according to the present invention, while FIG. 21B is a side elevational view thereof; and

FIG. 22A is a plan view showing the configuration of an eleventh embodiment of a semiconductor laser device according to the present invention, while FIG. 22B is a side elevational view thereof.

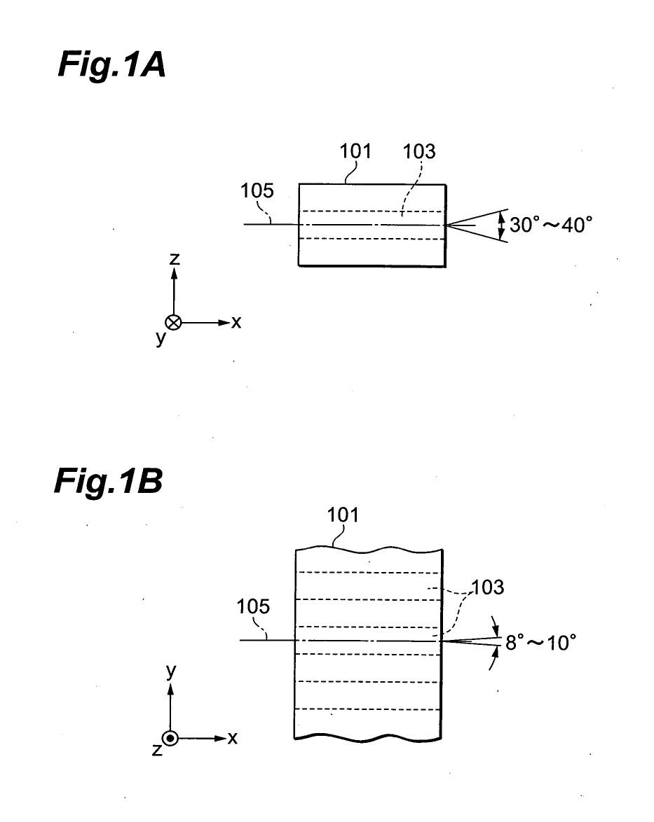

### BEST MODES FOR CARRYING OUT THE INVENTION

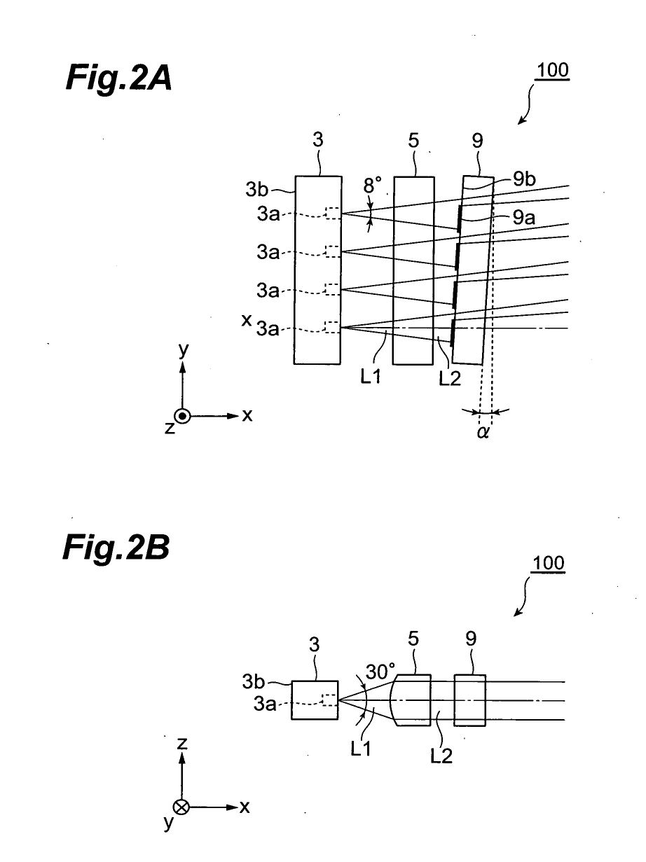

Each embodiment of a semiconductor laser device according to the present invention will hereinafter be described in detail with reference to FIGS. 2A-2B, 3, 4A-4B, 5-7, 8A-8B, 9, 10A-10B, 11, 12A-12B, 13, 14A-14B, 15, and 16A-22B. In addition, the same elements will be designated by the same reference numerals, and overlapping descriptions will be omitted.

### First Embodiment

FIG. 2A is a plan view (viewed in the z-axis direction) showing the configuration of a first embodiment of a semiconductor laser device according to the present invention, while FIG. 2B is a side elevational view (viewed in the y-axis direction) thereof. The semiconductor laser device 100 according to the first embodiment comprises a semiconductor laser array 3, a collimator lens 5, and an optical element 9. The coordinate axes (x-axis, y-axis, and z-axis) are set to be used in the following descriptions in such a manner that the direction in which the active layers 3a of the semiconductor laser array 3 are arranged is represented by the y-axis (second direction), that the direction in which laser beams are emitted is represented by the x-axis (first direction in which the active layers 3a extend), and that the direction perpendicular to both of them is represented by the z-axis (third direction).

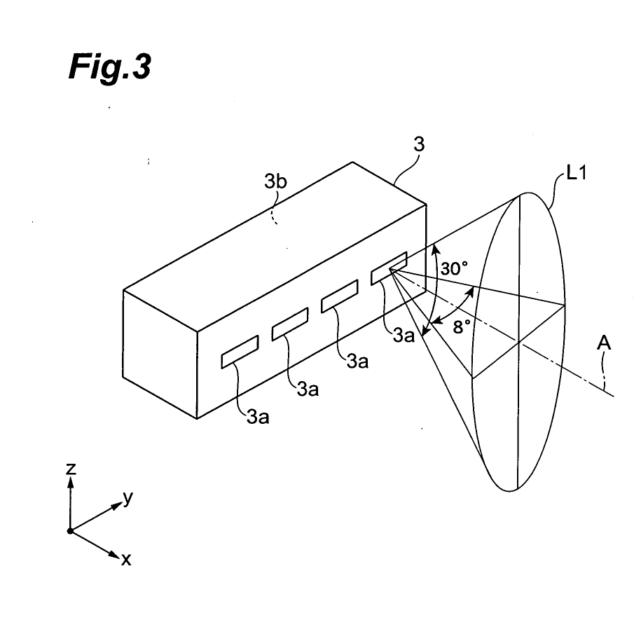

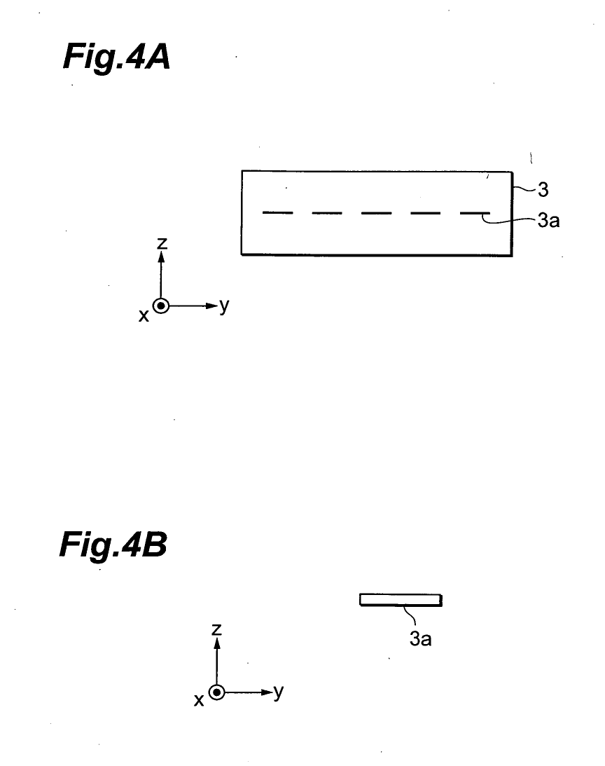

FIG. 3 is a perspective view showing the configuration of the semiconductor laser array 3. The semiconductor laser array 3 has plural active layers 3a arranged in parallel along the y-axis direction. Each active layer 3a emits a laser beam along an optical axis A, where the optical axis A passes through the center of each active layer 3a in parallel with the x-axis. FIG. 4A is a view showing the front end surface (beam emitting surface) of the semiconductor laser array 3, while FIG. 4B is a view showing the front end surface of each active layer 3a. The semiconductor laser array 3 has a structure in which active layers. 3a are arranged in line in the y-axis direction with a spacing of 500 μm within a width of 1 cm. The cross-section of the active layers 3a has a width of 150 μm and a thickness of 1 μm. Also, the front end surface of the semiconductor laser array 3 is coated with a reflection film having a reflectance of several % or less.

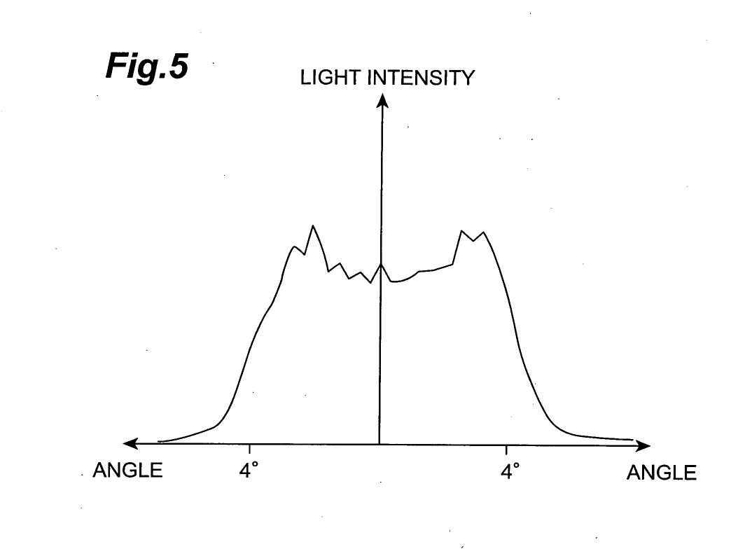

The laser beam L1 emitted from one active layer 3a has a spread angle of about 30° to 40° in the z-axis direction, while 8° to 10° in the y-axis direction centering on the optical axis A. FIG. 5 shows an optical intensity distribution in the y-axis direction of a beam L1 emitted from an active layer 3a. In the graph, the horizontal axis represents the angle from the optical axis A, while the vertical axis represents the optical intensity of the laser beam. As shown in FIG. 5, the intensity distribution shows not a Gaussian distribution but an irregular one.

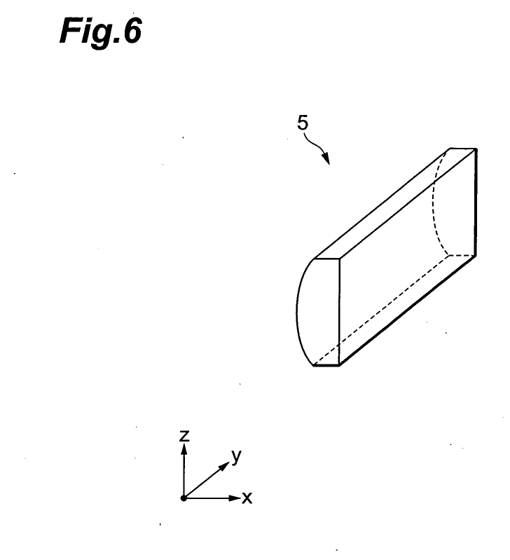

FIG. 6 is a perspective view showing the configuration of the collimator lens 5. The front and rear lens surfaces of the collimator lens 5 are cylindrical ones having a generatrix along the y-axis direction. The collimator lens 5 has dimensions of 0.4 mm to 1.5 mm in the x-axis direction, 12 mm in the y-axis direction, and 0.6 mm to 1.5 mm in the z-axis direction. The collimator lens 5 has an elongated shape along the y-axis direction.

The collimator lens 5 has a refracting function not within a plane including the generatrix (in the y-axis direction) but within a plane perpendicular to the generatrix. As described above, since beams emitted from the active layers 3a have a large spread angle in the vertical direction (z-axis direction), it is necessary to suppress the spread of the beams utilizing the refracting function to increase the beam collecting efficiency for the beams. The collimator lens 5 and the semiconductor laser array 3 are arranged in a positional relationship where the generatrix of the collimator lens 5 and the z-axis direction of the semiconductor laser array 3 intersect perpendicularly with each other. This arrangement allows beams emitted from the active layers 3a to be refracted and collimated within a plane perpendicular to the generatrix of the collimator lens 5. That is, the collimator lens 5 refracts and collimates the z-axis component of beams emitted from the respective active layers 3a. Also, in order to perform this collimating operation efficiently, the principal point of the collimator lens 5, which has a large NA (e.g., NA≧0.5) and a short focal length (e.g., f≦1.5 mm), is preferably arranged in the position the focal length away from the active layers 3a. This allows beams emitted from the active layers 3a of the semiconductor laser array 3 to enter the one collimator lens 5 wholly.

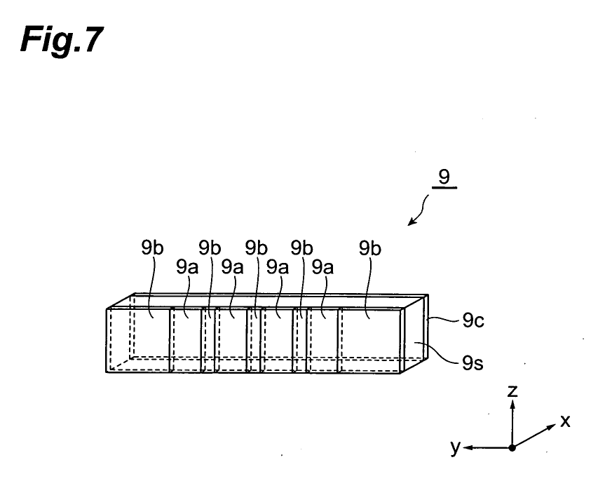

FIG. 7 is a perspective view showing the configuration of the optical element 9, when viewed from the side of the collimator lens 5. In the optical element 9 are provided, alternately along the y-axis direction, reflecting portions 9a for receiving and reflecting beams collimated in the z-axis direction by the collimator lens 5 and transmitting portions 9b for receiving and transmitting beams thus collimated. Then, the optical element 9 feedbacks at least part of beam reflected at each reflecting portion 9a to the active layer 3a that has emitted the beam. The optical element 9 also emits beam that transmits through each transmitting portion 9b outside.

The optical element 9 comprises a tabular substrate 9s comprised of translucent material such as glass or quartz, on one surface (on the collimator lens 5 side) of the tabular substrate 9s being formed the reflecting portions 9a and the transmitting portions 9b alternately along the y-axis direction. The reflecting portions 9a and the transmitting portions 9b each have a constant width in the y-axis direction and extend in the z-axis direction. That is, the optical element 9 is a stripe mirror having plural reflecting portions 9a arranged in a stripe manner.

The reflecting portions 9a preferably reflect incident beam from the collimator lens 5 at a high reflectance (e.g., 99.5% or more) and suitably employ a total reflection film, diffraction grating, or etalon, for example. The transmitting portions 9b preferably transmit incident beam from the collimator lens 5 at a high transmission (e.g., 99.5% or more) and suitably employ a reflection suppressing film, for example. Also, on the other surface (on the opposite side with respect to the collimator lens 5) of the substrate 9s is preferably formed a reflection suppressing film 9c.

One pair of adjacent reflecting portion 9a and transmitting portion 9b corresponds to one active layer 3a, and the borderline between the reflecting portion 9a and the transmitting portion 9b is parallel to the z-axis direction and exists within the cross-section of each beam reaching the optical element 9 from the collimator lens 5. Therefore, the reflecting portions 9a reflect a partial cross-sectional portion of each beam reaching the optical element 9 from the collimator lens 5 toward the collimator lens 5. Meanwhile, the transmitting portions 9b transmit a cross-sectional portion entering each transmitting portion 9b of each beam reaching the optical element 9 from the collimator lens 5.

In the optical element 9, the substrate 9s is preferably arranged 5 in an inclined manner by an angle of α with respect to a plane perpendicular to the optical axis of each beam emitted from the collimator lens 5, although it may be perpendicular to the optical axis of each beam emitted from the collimator lens 5, and the inclination α is preferably smaller than half of the spread angle β in the y-axis direction of each beam emitted from the collimator lens 5. This arrangement allows at least part of beam entering each reflecting portion 9a to enter perpendicularly, and reflected beam to follow the incident path reversely to be fedback to the active layer 3a. Representing the width of the reflecting portions 9a in the y-axis direction by W_{R}, the width of the transmitting portions 9b in the y-axis direction by W_{T}, and the cycle of the active layers 3a in the semiconductor laser array 3 by W_{L}, the sum of the widths W_{R} and W_{T} (W_{R}+W_{T}) equals W_{L}/cos α.

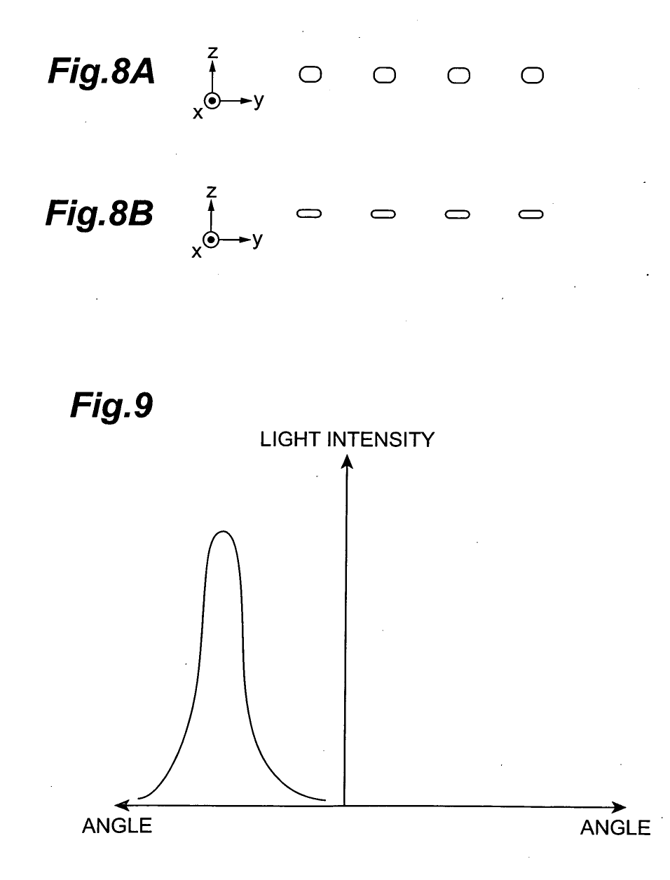

Next will be described the operation of the semiconductor laser device 100 according to the first embodiment with reference to FIGS. 2A to 2B and FIGS. 8A to 8B. FIG. 8A shows cross-sections (emitting patterns) of beams generated in the active layers 3a before entering the collimator lens 5, while FIG. 8B shows cross-sections of beams emitted from the active layers 3a after passing through the collimator lens 5.

The beam L1 is emitted in the x-axis direction from each active layer 3a of the semiconductor laser array 3. The beam L1 has a spread angle of 8° in the y-axis direction, while 30° in the z-axis direction centering on the optical axis (indicated by the alternate long and short dash line in FIGS. 2A and 2B). The vertical length (in the z-axis direction) of the cross-section of the active layers 3a is one-hundredth to one two-hundredths of the horizontal length (in the y-axis direction).

Therefore, the cross-section of the beam L1 has a horizontally elongated shape when emitted from the active layers 3a. Beams emitted from the active layers 3a spread until reaching the collimator lens 5 (FIG. 8A). In addition, the vertical length of the cross-section of beams entering the collimator lens 5 depends on the focal length of the collimator lens 5.

The beams L1 emitted from the active layers 3a enter the collimator lens 5. The collimator lens 5 refracts the beams L1 within a plane perpendicular to the y-axis (parallel to the xz-plane), and then emits the refracted beams in the x-axis direction as beams L2. The beams L2 are to have a spread angle of about 0.2° in the z-axis direction, while not refracted in the y-axis direction. That is, since the horizontal spread angle is larger than the vertical spread angle after being emitted from the collimator lens 5, the cross-section of the beams has a horizontally elongated shape at a position away from the collimator lens 5 (FIG. 8B). Since the collimator lens 5 has no refracting function within a plane including the y-axis, the spread angle in the y-axis direction is the same as that of the beams L1.

The beams L2 refracted by the collimator lens 5 enter the optical element 9 before adjacent beams intersect with each other. In the optical element 9, the borderline extending in the z-axis direction between adjacent reflecting portion 9a and transmitting portion 9b exists within the cross-section of the optical path of each beam L2, part of each beam L2 emitted from the collimator lens 5 enters the reflecting portion 9a, while the rest thereof enters the transmitting portion 9b. Also, at least part of beam entering the reflecting portion 9a enters perpendicularly thereto.

The beam reflected at each reflecting portion 9a, as part of each beam L2, follows the optical path from the active layer 3a to the reflecting portion 9a reversely to be fedback to the active layer 3a. The fedback beam returns to the active layer 3a of the semiconductor laser array 3 to be amplified in the active layer 3a, and further reaches the end surface (emitting surface), through which a laser beam is to be emitted, through the rear end surface (reflecting surface) of the semiconductor laser array 3. The beam reflected toward the rear end surface, as part of the beam that has reached the emitting surface, is emitted again in the x-axis direction from the active layer 3a through the rear end surface. The part of the emitted beam reaches the optical element 9 again through the optical path, and only part of beam after reflection at the reflecting portion 9a is again fedback reversely through the optical path to return to the active layer 3a.

The arrangement above forms an external resonator between the reflecting portions 9a and the active layers 3a and causes stimulated emission in the active layers 3a due to resonance of part of beams in the external resonator. This causes the spatial transverse mode of laser beams to be emitted in a stimulated manner to be brought close to a single mode. Meanwhile, beam that enters each transmitting portion 9b of the optical element 9 from the collimator lens 5 transmits via the transmitting portion 9b to be emitted outside the semiconductor laser device 1. This is the final output from the semiconductor laser device 100.

Thus, the semiconductor laser device 100 according to the first embodiment comprises a resonant optical path including the optical path of beams reflected at the reflecting portions 9a and an output optical path including the optical path of beams that transmit via the transmitting portions 9b. Accordingly, in the semiconductor laser device 100, the resonance of beams generated in the active layers 3a of the semiconductor laser array 3 on the resonant optical path causes the spatial transverse mode to be brought close to a single mode, and the closeness of the spatial transverse mode to a single mode allows laser beams having a small spread angle to be emitted outside from the output optical path. Therefore, in accordance with the semiconductor laser device 100, it is possible to reduce the spread angle of the final output. Also, since the resonant optical path and the output optical path are divided with the arrangement of the reflecting portions 9a and the transmitting portions 9b, it is possible to obtain stronger resonant beam and thereby stronger output beam relative to the case of forming an optical path of resonant beam and an optical path of output beam using a half mirror, and the like.

The optical intensity of a beam that transmits through each transmitting portion 9b (final output from the semiconductor laser device 100) is distributed with respect to the y-axis direction as shown in FIG. 9. In comparison with the optical intensity distribution of a beam emitted from each active layer 3a (refer to FIG. 5), the optical intensity distribution of the final output from the semiconductor laser device 100 has a single and further sharp peak. That is, laser beams emitted from the semiconductor laser device 100 have a small spread angle. The spread angle, although varying depending on conditions such as the size of the active layers 3a, is about 0.5 to 1.5° in the case of the semiconductor laser device 100, which is smaller relative to the spread angle 8° of beams emitted from the active layers 3a.

The peak position and peak intensity of the intensity distribution vary with the change of the inclination α of the optical element 9. In the semiconductor laser device 100, in order to achieve stronger output beam, the inclination of the optical element 9 with which the peak intensity is maximized may be found in advance, and the installation angle α may be set to the found angle.

Also, in the optical element 9, in the case of using a diffraction grating or an etalon formed on one surface of the substrate 9s as reflecting portions 9a, laser beams output from the semiconductor laser device 100 have a small spread angle as well as a narrow wavelength bandwidth due to the reflecting wavelength selecting function of the diffracting grating or the etalon.

### Second Embodiment

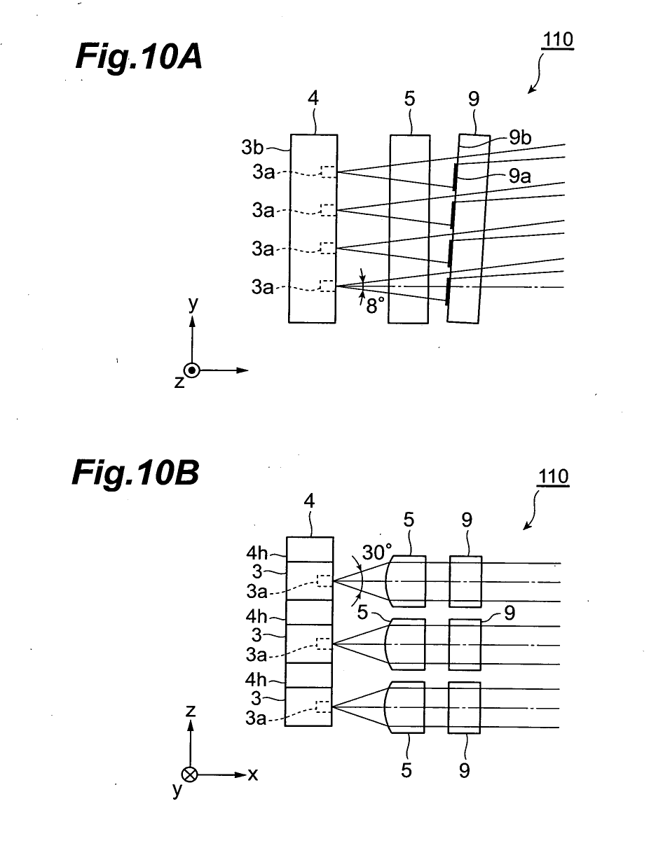

FIG. 10A is a plan view (viewed in the z-axis direction) showing the configuration of a second embodiment of a semiconductor laser device 110 according to the present invention, while FIG. 10B is a side elevational view (viewed in the y-axis direction) thereof. The semiconductor laser device 110 according to the second embodiment comprises a semiconductor laser array stack 4, collimator lenses 5, and optical elements 9.

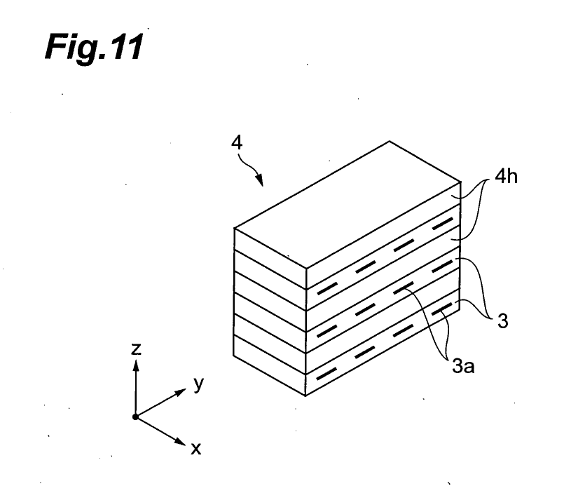

FIG. 11 is a perspective view showing the configuration of the semiconductor laser array stack 4. As shown in FIG. 11, the semiconductor laser array stack 4 has a structure in which plural semiconductor laser arrays 3 and plural heat sinks 4h are arranged alternately along the z-axis direction. The heat sinks 4h cool the semiconductor laser arrays 3. Also, the heat sinks 4h each have a cooling channel formed by combining tabular members comprised of copper. Cooling water circulates in the cooling channel.

Each semiconductor laser array 3 has the same configuration as that of the semiconductor laser array 3 in the first embodiment (FIGS. 3, 4A and 4B). Each collimator lens 5 has the same configuration as that of the collimator lens 5 in the first embodiment (FIG. 6). Each optical element 9 also has the same configuration as that of the optical element 9 in the first embodiment (FIG. 7). Then, the number of semiconductor laser arrays 3, collimator lenses 5, and the optical elements 9 is the same, where the collimator lenses 5 are provided in a one-to-one relationship with the semiconductor laser arrays 3, and the optical elements 9 are provided in a one-to-one relationship with the collimator lenses 5. The semiconductor laser arrays 3, collimator lenses 5, and optical elements 9 of each group are arranged in the same manner as in the first embodiment.

In the semiconductor laser device 110 according to the second embodiment, the resonance of beam generated in the active layers 3a of the semiconductor laser arrays 3 in the resonant optical path causes the spatial transverse mode to be brought close to a single mode, and the closeness of the spatial transverse mode to a single mode allows laser beams having a small spread angle to be output outside from the output optical path. Therefore, in accordance with the semiconductor laser device 110, it is possible to reduce the spread angle of the final output.

### Third Embodiment

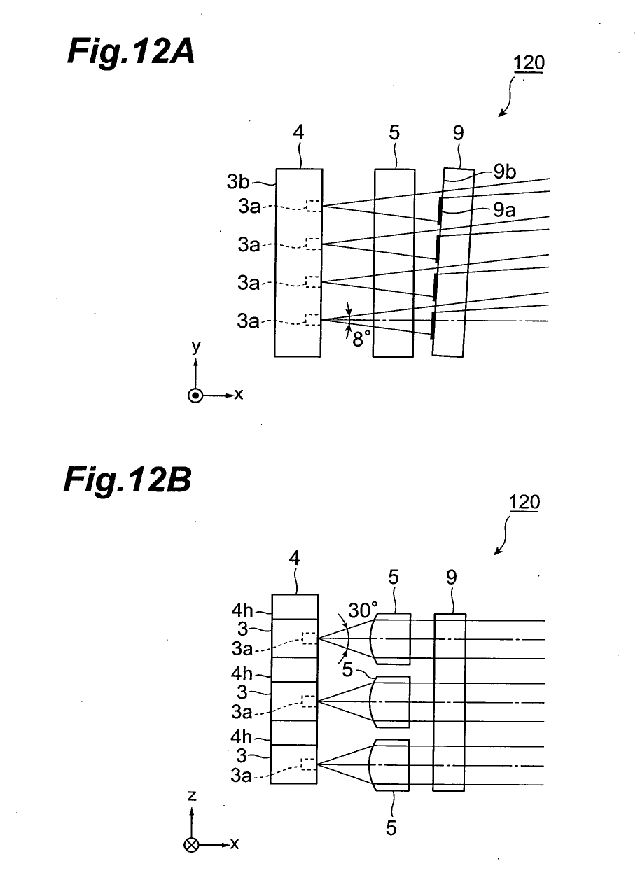

FIG. 12A is a plan view (viewed in the z-axis direction) showing the configuration of a third embodiment of a semiconductor laser device according to the present invention, while FIG. 12B is a side elevational view (viewed in the y-axis direction) thereof. The semiconductor laser device 120 according to the third embodiment differs from the semiconductor laser device 110 according to the second embodiment in that only one optical element 9 is provided. Except for the difference, the configuration of the semiconductor laser device 120 is completely the same as that of the semiconductor laser device 110 according to the second embodiment, and the descriptions will be omitted.

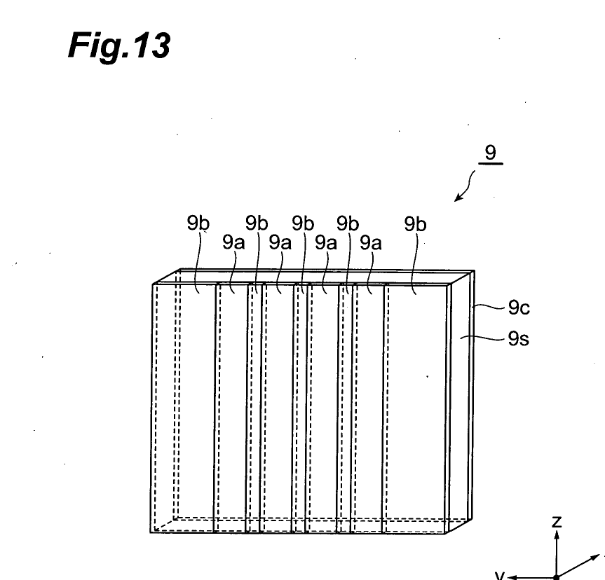

FIG. 13 is a perspective view showing the configuration of an optical element 9 to be applied to the semiconductor laser device 120 according to the third embodiment, when viewed from the collimator lens 5 side. The optical element 9 to be applied to the third embodiment has a different width in the z-axis direction from that of the optical elements in the first and second embodiments. That is, the length of the optical element 9 to be applied to the third embodiment in the z-axis direction is about equal to or more than that of the semiconductor laser array stack 4 in the z-axis direction. Then, the reflecting portions 9a and transmitting portions 9b are provided alternately along the y-axis direction, and each extend continuously along the z-axis direction.

The semiconductor laser device 120 according to the third embodiment operates in the same manner as and exhibits the same effect as the semiconductor laser device 110 according to the second embodiment. In addition, since only one optical element 9 is required, it is easy to assemble the semiconductor laser device 120 and adjust the optical axis thereof.

### Fourth Embodiment

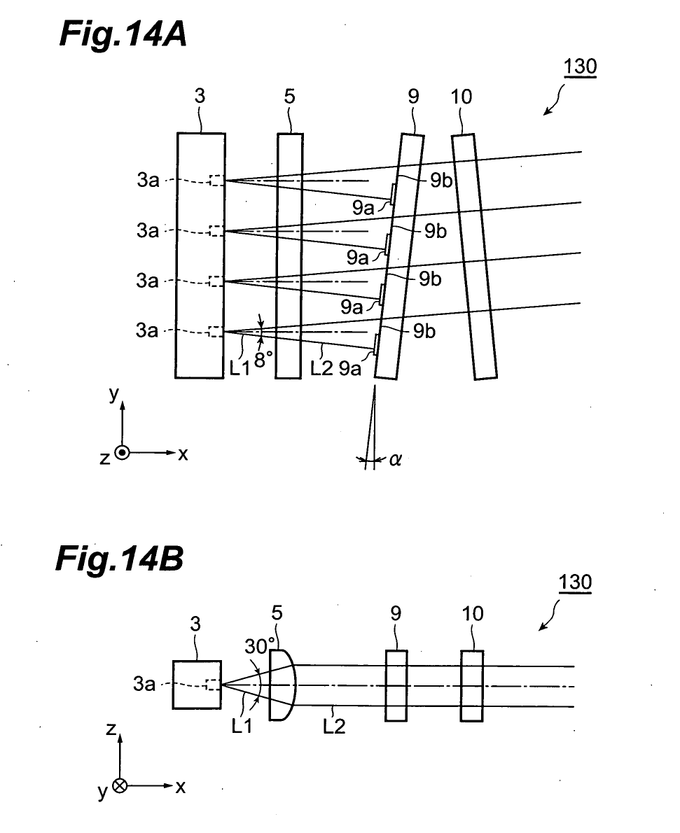

Next will be described a fourth embodiment of a semiconductor laser device according to the present invention. FIG. 14A is a plan view (viewed in the z-axis direction) showing the configuration of the fourth embodiment of a semiconductor laser device according to the present invention, while FIG. 14B is a side elevational view (viewed in the y-axis direction) thereof. The semiconductor laser device 130 according to the fourth embodiment comprises a semiconductor laser array 3, a collimator lens 5, an optical element 9, and a wavelength selecting element 10.

The semiconductor laser array 3 has the same configuration as that of the semiconductor laser array 3 in the first embodiment (FIGS. 3, 4A and 4B). The semiconductor laser array 3 has plural active layers 3a arranged in parallel along the y-axis direction. Each active layer 3a emits a laser beam along an optical axis A. Also, the semiconductor laser array 3 has a structure in which active layers 3a are arranged in line in the y-axis direction with a spacing of 300 μm to 500 μm within a width of lcm. The cross-section of the active layers 3a has a width of 100 μm to 200 μm and a thickness of 1 μm. Also, the front end surface of the semiconductor laser array 3 is coated with a reflection suppressing film having a reflectance of several % or less.

The collimator lens 5 has the same configuration as that in the first embodiment (FIG. 6). The front and rear lens surfaces of the collimator lens 5 are cylindrical ones having a generatrix along the y-axis direction. The collimator lens 5 has dimensions of 0.4 mm to 1.5 mm in the x-axis direction, 12 mm in the y-axis direction, and 0.6 mm to 1.5 mm in the z-axis direction. The collimator lens 5 has an elongated shape along the y-axis direction.

The collimator lens 5 has a refracting function not within a plane including the generatrix (in the y-axis direction) but within a plane perpendicular to the generatrix. As described above, since beams emitted from the active layers 3a have a large spread angle in the vertical direction, it is necessary to suppress the spread of the beams utilizing the refracting function to increase the beam collecting efficiency for the beams. The collimator lens 5 and the semiconductor laser array 3 are arranged in a positional relationship where the generatrix of the collimator lens 5 and the semiconductor laser array 3 in the z-axis direction intersect perpendicularly with each other. This arrangement allows beams emitted from the active layers 3a to be refracted and collimated within a plane perpendicular to the generatrix of the collimator lens 5. That is, the collimator lens 5 refracts and collimates the components of beams in the z-axis direction emitted from the active layers 3a. Also, in order to perform this collimating operation efficiently, the principal point of the collimator lens 5, which has a large NA (e.g., NA≧0.5) and a short focal length (e.g., f≦1.5 mm), is arranged in the position the focal length away from the active layers 3a. This allows all beams emitted from the active layers 3a of the semiconductor laser array 3 to enter the one collimator lens 5.

The optical element 9 also has the same configuration as that in the first embodiment (FIG. 7). In the optical element 9 are provided, alternately along the y-axis direction, reflecting portions 9a for receiving and reflecting beams collimated in the z-axis direction by the collimator lens 5 and transmitting portions 9b for receiving and transmitting beams thus collimated. Then, the optical element 9 feedbacks at least part of beam reflected at each reflecting portion 9a to the active layer 3a that has emitted the beam. The optical element 9 also transmits beam that enters each transmitting portion 9b.

The optical element 9 comprises a tabular substrate 9s comprised of translucent material such as glass or quartz, on one surface (on the collimator lens 5 side) thereof being formed the reflecting portions 9a and the transmitting portions 9b alternately along the y-axis direction. The reflecting portions 9a and the transmitting portions 9b each have a constant width in the y-axis direction and extend in the z-axis direction. That is, the optical element 9 is a stripe mirror having plural reflecting portions 9a formed in a stripe manner.

The reflecting portions 9a preferably reflect incident beam from the collimator lens 5 at a high reflectance (e.g., 99.5% or more) and preferably employ a total reflection film, for example. The transmitting portions 9b preferably transmit incident beam from the collimator lens 5 at a high transmission (e.g., 99.5% or more) and preferably employ a reflection suppressing film, for example. Also, on the other surface (on the opposite side with respect to the collimator lens 5) of the substrate 9s, a reflection suppressing film 9c is preferably formed.

One pair of adjacent reflecting portion 9a and transmitting portion 9b corresponds to one active layer 3a, and the borderline between the reflecting portion 9a and the transmitting portion 9b is parallel in the z-axis direction and is within the cross-section of each beam reaching the optical element 9 from the collimator lens 5. Therefore, the reflecting portions 9a reflect a partial cross-sectional portion of each beam reaching the optical element 9 from the collimator lens 5 toward the collimator lens 5. Meanwhile, the transmitting portions 9b transmit a cross-sectional portion entering each transmitting portion 9b of each beam reaching the optical element 9 from the collimator lens 5.

In the optical element 9, the substrate 9s is preferably arranged in an inclined manner by an angle of α with respect to a plane perpendicular to the optical axis of each beam emitted from the collimator lens 5, although the substrate 9s may be perpendicular to the optical axis of each beam emitted from the collimator lens 5, and the inclination α is preferably smaller than half of the spread angle β in the y-axis direction of each beam emitted from the collimator lens 5. This arrangement allows at least part of beam entering each reflecting portion 9a to enter perpendicularly, and reflected beam to follow the incident path reversely to be fedback to the active layer 3a.

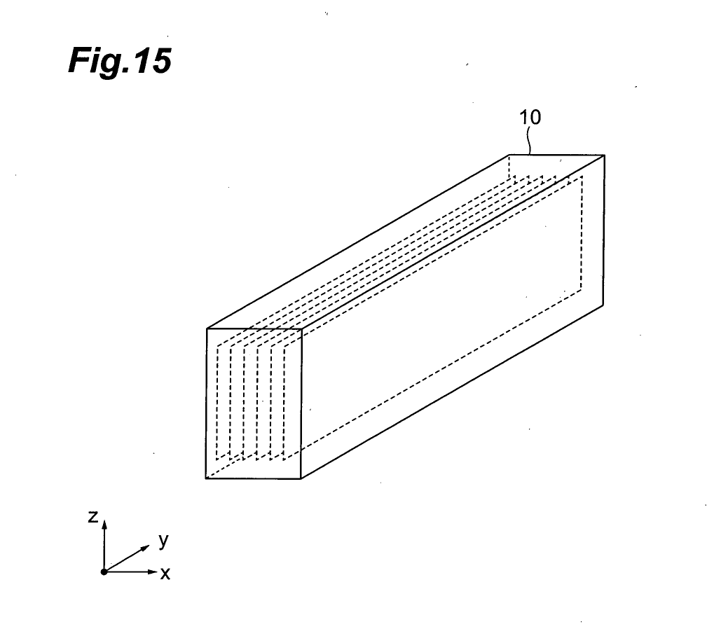

FIG. 15 is a perspective view showing the configuration of the wavelength selecting element 10 to be applied to the fourth embodiment. The wavelength selecting element 10 has a cyclical refractive index distributed in the thickness direction (approximately in the x-axis direction), and can cause Bragg reflection of part of the incident beam. Each beam that is outputted from the collimator lens 5 and transmits through each transmitting portion 9b of the optical element 9 enters the wavelength selecting element 10 perpendicularly, and then part of beam having a specific wavelength that satisfies the Bragg condition in the perpendicularly entering beam is reflected. Then, the wavelength selecting element 10 feedbacks at least part of the reflected beam to the active layer 3a that has emitted the beam, while transmitting the rest of the beam having the specific wavelength. Then, between the reflecting portions 9a of the optical element 9 and the wavelength selecting element 10 is formed a laser resonator. In addition, as such a wavelength selecting element 10 is known, for example, a product LuxxMaster™ manufactured by PD-LD Inc.

Next will be described the operation of the semiconductor laser device 130 according to the fourth embodiment. The beam L1 is emitted in the x-axis direction from each active layer 3a of the semiconductor laser array 3. The beam L1 has a spread angle of 8° in the y-axis direction, while 30° in the z-axis direction centering on the optical axis (indicated by the alternate long and short dash line in FIGS. 14A and 14B). The vertical length (in the z-axis direction) of the cross-section of the active layers 3a is one-hundredth to one two-hundredths of the horizontal length (in the y-axis direction). Therefore, the cross-section of the beam L1 has a horizontally elongated shape when outgoing from the active layers 3a. Beams emitted from the active layers 3a spread until reaching the collimator lens 5. In addition, the vertical length of the cross-section of beams entering the collimator lens 5 depends on the focal length of the collimator lens 5.

The beams L1 emitted from the active layers 3a enter the collimator lens 5. The collimator lens 5 refracts the beams L1 within a plane perpendicular to the y-axis (parallel to the xz-plane), and then emits the refracted fluxes in the x-axis direction as beams L2. The beams L2 are to have a spread angle of about 0.20 in the z-axis direction, while not refracted in the y-axis direction. That is, since the horizontal spread angle is larger than the vertical spread angle after being emitted from the collimator lens 5, the cross-section of the beams has a horizontally elongated shape at a position away from the collimator lens 5. Since the collimator lens 5 has no refracting function within a plane including the y-axis, the spread angle in the y-axis direction is the same as that of the beams L1.

The beams L2 refracted by and emitted from the collimator lens 5 enter the optical element 9 before adjacent beams intersect with each other. Beam entering each reflecting portion 9a in each beam that enters the optical element 9 is reflected at the reflecting portion 9a, while beam entering each transmitting portion 9b transmits via the transmitting portion 9b.

At least part of beam emitted from the collimator lens 5 and reflected at each reflecting portion 9a of the optical element 9 follows the optical path from the active layer 3a to the reflecting portion 9a of the optical element 9 reversely to be fedback to the active layer 3a. The fedback beam returns to the active layer 3a of the semiconductor laser array 3 to be amplified in the active layer 3a, and further reaches the end surface (outgoing surface), through which a laser beam is to be emitted, through the rear end surface (reflecting surface) of the semiconductor laser array 3. The beam reflected toward the rear end surface in the beam that has reached the outgoing surface is emitted again in the x-axis direction from the active layer 3a through the rear end surface. The part of the emitted beam reaches the optical element 9 again through the optical path (resonant optical path).

Meanwhile, the beam that is emitted from the collimator lens 5 and transmits through each transmitting portion 9b of the optical element 9 enters the wavelength selecting element 10. The part of beam having a specific wavelength in the beam entering the wavelength selecting element 10 is subject to Bragg reflection by the wavelength selecting element 10, while the rest transmits through the wavelength selecting element 10. At least part of the reflected beam follows the optical path from the active layer 3a to the wavelength selecting element 10 reversely to be fedback to the active layer 3a. The fedback beam returns to the active layer 3a of the semiconductor laser array 3 to be amplified in the active layer 3a, and further reaches the end surface (outgoing surface), through which a laser beam is to be emitted, through the rear end surface (reflecting surface) of the semiconductor laser array 3. The beam reflected toward the rear end surface in the beam that has reached the outgoing surface is emitted again in the x-axis direction from the active layer 3a through the rear end surface. The part of the emitted beam reaches the optical element 9 again through the optical path.

The arrangement above forms an external resonator between the reflecting portions 9a of the optical element 9 and the wavelength selecting element 10, the active layers 3a being positioned within the resonator, and causes stimulated emission in the active layers 3a due to resonance of part of beams in the external resonator. This causes the spatial transverse mode of laser beams to be emitted in a stimulated manner to be brought close to a single mode. Meanwhile, the beam that transmits through the wavelength selecting element 8 is emitted outside the semiconductor laser device 1. This is the final output from the semiconductor laser device 1.

Thus, the semiconductor laser device 130 according to the fourth embodiment is to comprise a resonant optical path including the optical path of beams reflected at the reflecting portions of the optical element 9 and an output optical path including the optical path of beams that transmit via the transmitting portions. Accordingly, in the semiconductor laser device 130, the resonance of beam generated in the active layers 3a of the semiconductor laser array 3 in the resonant optical path causes the spatial transverse mode to be brought close to a single mode, and the closeness of the spatial transverse mode to a single mode allows laser beams having a small spread angle to be output outside from the output optical path. Therefore, in accordance with the semiconductor laser device 130, it is possible to reduce the spread angle of the final output.

Also, since the resonant optical path and the output optical path are divided with the arrangement of the reflecting portions 9a and the transmitting portions 9b of the optical element 9, it is possible to obtain stronger resonant beam and thereby stronger output beam than that in the case of forming an optical path of resonant beam and an optical path of output beam using a half mirror, and the like.

Further, since the semiconductor laser device 130 according to the fourth embodiment comprises a wavelength selecting element 10 on one side of the resonator, beam having a specific wavelength and selected by the wavelength selecting element 10 is resonated selectively by the external resonator, whereby the beam having the specific wavelength can be output outside. Therefore, in accordance with the semiconductor laser device 130, it is possible to reduce the spectrum width of the final output.

### Fifth Embodiment

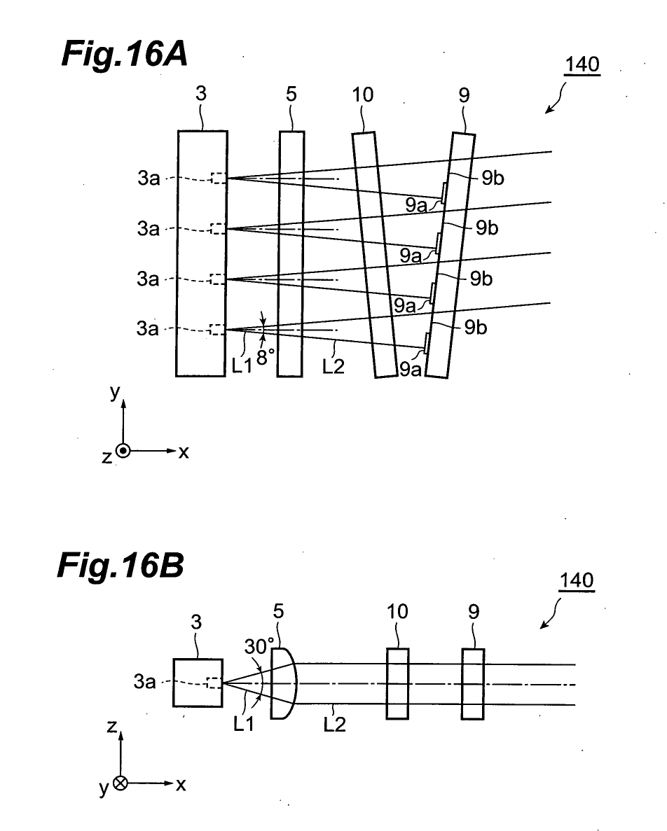

FIG. 16A is a plan view (viewed in the z-axis direction) showing the configuration of a fifth embodiment of a semiconductor laser device according to the present invention, while FIG. 16B is a side elevational view (viewed in the y-axis direction) thereof. The semiconductor laser device 140 according to the fifth embodiment comprises a semiconductor laser array 3, a collimator lens 5, a wavelength selecting element 10, and an optical element 9.

The semiconductor laser device 140 according to the second embodiment differs from the semiconductor laser device 130 according to the fourth embodiment (FIGS. 14A and 14B) in that the wavelength selecting element 10 is provided between the collimator lens 5 and the optical element 9. Except for the difference, the configuration of the semiconductor laser device 140 is the same as that of the semiconductor laser devices 100 and 130 according to the first and fourth embodiments, and the descriptions will be omitted.

The optical element 9 reflects beam entering each reflecting portion 9a in each beam that is outputted from the collimator lens 5 and transmits through the wavelength selecting element 10 to be fedback to the active layers 3a, while transmitting beam entering each transmitting portion 9b to be output outside. Each beam output from the collimator lens 5 enters the wavelength selecting element 10 perpendicularly, and then part of beam having a specific wavelength that satisfies the Bragg condition in the perpendicularly entering beam is reflected. Then, the wavelength selecting element 10 feedbacks at least part of the reflected beam to the active layer 3a that has emitted the beam, while transmitting the rest of the beam having the specific wavelength.

Then, between the reflecting portions 9a of the optical element 9 and the wavelength selecting element 10, an external resonator is formed. The active layers 3a are positioned within the resonator, and there occurs stimulated emission in the active layers 3a due to resonance of part of beams in the external resonator. In accordance with the semiconductor laser device 140 according to the fifth embodiment, it is also possible to reduce the spread angle and the spectrum width of the final output.

### Sixth Embodiment

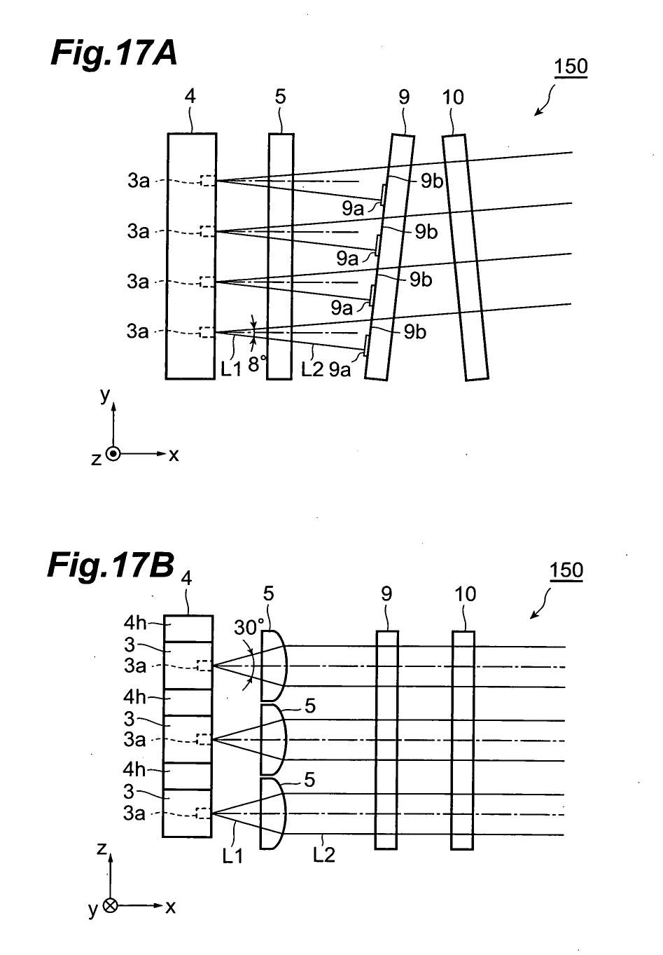

FIG. 17A is a plan view (viewed in the z-axis direction) showing the configuration of a sixth embodiment of a semiconductor laser device according to the present invention, while FIG. 17B is a side elevational view (viewed in the y-axis direction) thereof. The semiconductor laser device 150 according to the sixth embodiment comprises a semiconductor laser array stack 4, a collimator lens 5, an optical element 9, and a wavelength selecting element 10.

The semiconductor laser device 150 according to the sixth embodiment differs from the semiconductor laser device 130 according to the fourth embodiment (FIGS. 14A and 14B) in that the semiconductor 5 laser array stack 4 including plural semiconductor laser arrays 3 is provided, and that the optical element 9 and the wavelength selecting element 10 each have a larger dimension in the z-axis direction accordingly. Except for the difference, the configuration of the semiconductor laser device 150 is the same as that of the semiconductor laser device 130 according to the fourth embodiment, and the descriptions will be omitted.

The semiconductor laser array stack 4 has the same configuration as that of the semiconductor laser array stack 4 applied to the second embodiment (FIG. 11). As shown in FIG. 11, the semiconductor laser array stack 4 has a structure in which plural semiconductor laser arrays 3 and plural heat sinks 4h are arranged alternately along the z-axis direction. The heat sinks 4h cool the semiconductor laser arrays 3. Also, the heat sinks 4h each have a cooling channel formed by combining tabular members comprised of copper. Cooling water circulates in the cooling channel.

Each semiconductor laser array 3 has the same configuration as that of the semiconductor laser array 3 in the first embodiment (FIGS. 3, 4A and 4B). Each collimator lens 5 also has the same configuration as that in the first embodiment (FIG. 6). Each optical element 9 has the same configuration as that in the third embodiment (FIG. 13), and has about the same height as that in the z-axis direction of the semiconductor laser array stack 4. Further, the wavelength selecting element 10 has approximately the same configuration as that in the fourth embodiment (FIG. 15), and has about the same height as that in the z-axis direction of the semiconductor laser array stack 4. The semiconductor laser array 3, collimator lens 5, wavelength selecting element 10, and optical element 9 are arranged in the same manner as in the fourth embodiment.

In the semiconductor laser device 150 according to the sixth embodiment, the resonance of beam generated in the active layers 3a of the semiconductor laser arrays 3 in the resonant optical path causes the spatial transverse mode to be brought close to a single mode, and the closeness of the spatial transverse mode to a single mode allows laser beams having a small spread angle to be output outside from the output optical path. Therefore, in accordance with the semiconductor laser device 150, it is possible to reduce the spread angle of the final output. Also, in accordance with the semiconductor laser device 150, since the wavelength selecting element 10 is provided, it is possible to reduce the spectrum width of the final output.

In addition, since only one pair of wavelength selecting element 10 and optical element 9 may be required, it is easy to assemble the semiconductor laser device 150 and adjust the optical axis thereof.

### Seventh Embodiment

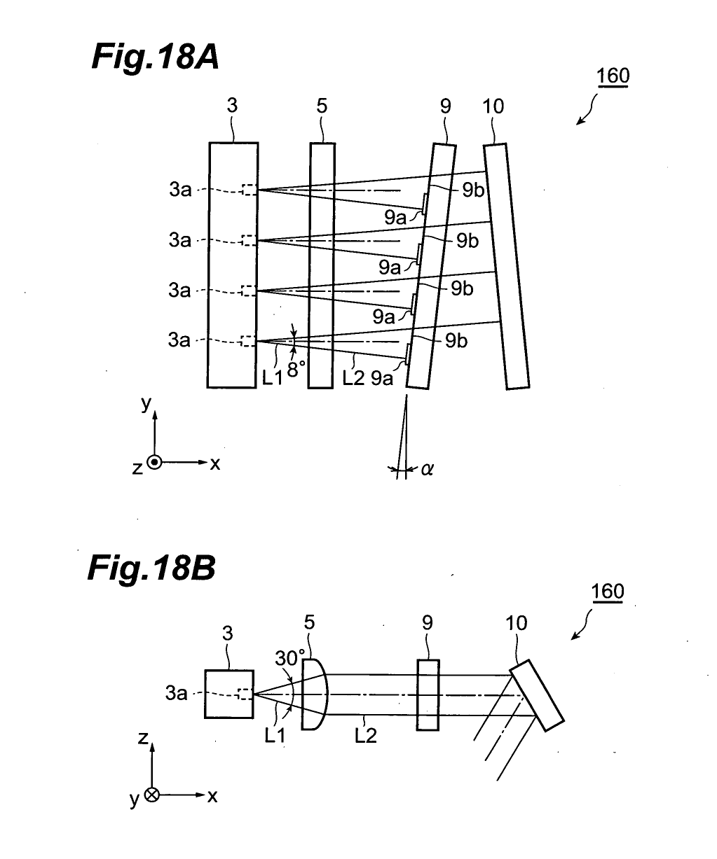

FIG. 18A is a plan view (viewed in the z-axis direction) showing the configuration of a seventh embodiment of a semiconductor laser device according to the present invention, while FIG. 18B is a side elevational view (viewed in the y-axis direction) thereof. The semiconductor laser device 160 according to the seventh embodiment comprises a semiconductor laser array 3, a collimator lens 5, an optical element 9, and a wavelength selecting element 10.

The semiconductor laser device 160 according to the seventh embodiment differs from the semiconductor laser device 130 according to the fourth embodiment (FIGS. 14A and 14B) in that the wavelength selecting element 10 is a reflective Raman-Nath diffraction grating element. Except for the difference, the configuration of the semiconductor laser device 160 is the same as that of the semiconductor laser devices 100 and 130 according to the first and fourth embodiments, and the descriptions will be omitted.

The wavelength selecting element 10 in the seventh embodiment reflects each beam that is refracted through the collimator lens 5 and transmits through each transmitting portion 9b of the optical element 9 through Raman-Nath diffraction. Then, the wavelength selecting element 10 feedbacks beam of a specific diffraction order (e.g., first order) having a specific wavelength in the diffracted beam to the active layer that has emitted the beam, while outputting beam of an order other than the specific diffraction order (e.g., zeroth order) having the specific wavelength outside.

In the semiconductor laser device 160 according to the seventh embodiment having such a structure, beams emitted from the active layers 3a of the semiconductor laser array 3, which spread in the z-axis direction from the active layers 3a, are refracted through the collimator lens 5 to be approximately parallel in the z-axis direction to enter the optical element 9. In the optical element 9 are provided reflecting portions 9a for reflecting each beam and transmitting portions 9b for transmitting each beam. At least part of beam reflected at each reflecting portion 9a of the optical element 9 is fedback to the active layer 3a that has emitted the beam. Also, beam that transmits through each transmitting portion 9b of the optical element 9 enters the wavelength selecting element 10 in which beam can be reflected through Raman-Nath diffraction. Beam of a specific diffraction order having a specific wavelength in the beam that enters the wavelength selecting element 10 is fedback to the active layer 3a that has emitted the beam. The arrangement above forms an external resonator between the reflecting portions 9a of the optical element 9 and the wavelength selecting element 10, and causes stimulated emission in active layers 3a positioned within the resonator to achieve laser oscillation. Meanwhile, beam of an order other than the specific diffraction order having the specific wavelength in the beam that enters the wavelength selecting element 10 is emitted outside as output beam of the semiconductor laser device 160. In accordance with the semiconductor laser device 160, it is also possible to reduce the spread angle and the spectrum width of the final output.

### Eighth Embodiment

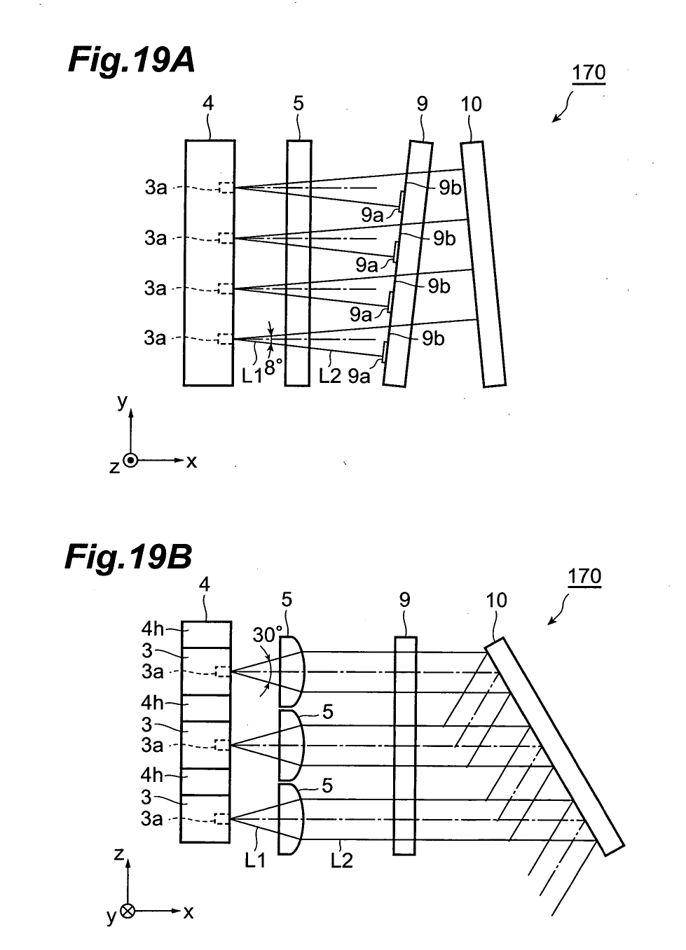

FIG. 19A is a plan view (viewed in the z-axis direction) showing the configuration of an eighth embodiment of a semiconductor laser device according to the present invention, while FIG. 19B is a side elevational view (viewed in the y-axis direction) thereof. The semiconductor laser device 170 according to the eighth embodiment comprises a semiconductor laser array stack 4, a collimator lens 5, an optical element 9, and a wavelength selecting element 10.

The semiconductor laser device 170 according to the eighth embodiment differs from the semiconductor laser device 150 according to the sixth embodiment (FIGS. 17A and 17B) in that the wavelength selecting element 10 is a reflective Raman-Nath diffraction grating element. Except for the difference, the configuration of the semiconductor laser device 170 is the same as that of the semiconductor laser devices 150 according to the sixth embodiment, and the descriptions will be omitted.

The wavelength selecting element 10 in the eighth embodiment reflects each beam that is refracted through the collimator lens 5 and transmits through each transmitting portion 9b of the optical element 9 through Raman-Nath diffraction. Then, the wavelength selecting element 10 feedbacks beam of a specific diffraction order (e.g., first order) having a specific wavelength in the diffracted beam to the active layer 3a that has emitted the beam, while outputting beam of an order other than the specific diffraction order (e.g., zeroth order) having the specific wavelength outside.

In the semiconductor laser device 170, each semiconductor laser array 3 included in the semiconductor laser array stack 4 operates in the same manner as in the semiconductor laser device 160 according to the seventh embodiment. That is, the beam that transmits through each transmitting portion 9b of the optical element 9 enters the wavelength selecting element 10 in which beam can be reflected through Raman-Nath diffraction. Beam of a specific diffraction order having a specific wavelength in the beam that enters the wavelength selecting element 10 is fedback to the active layer 3a that has emitted the beam. The arrangement above forms an external resonator between the reflecting portions 9a of the optical element 9 and the wavelength selecting element 10, and causes stimulated emission in active layers 3a positioned within the resonator to achieve laser oscillation. Meanwhile, beam of an order other than the specific diffraction order having the specific wavelength in the beam that enters the wavelength selecting element 10 is emitted outside as output beam of the semiconductor laser device 170. In accordance with the semiconductor laser device 170, it is also possible to reduce the spread angle and the spectrum width of the final output.

(Exemplary Variation)

The present invention is not restricted to the above-described embodiments, and various modifications may be made. For example, in the case of applying a semiconductor laser array stack 4 as in the sixth embodiment (FIGS. 17A and 17B), a wavelength selecting element 10 may be provided between the collimator lens 5 and the optical element 9 as in the fifth embodiment (FIGS. 16A and 16B). Also, in the sixth embodiment, the optical element 9 or the wavelength selecting element 10 may have the same dimensions as in the fourth embodiment, where the optical element 9 or the wavelength selecting element 10 is to be provided correspondingly to each semiconductor laser array 3.

### Ninth Embodiment

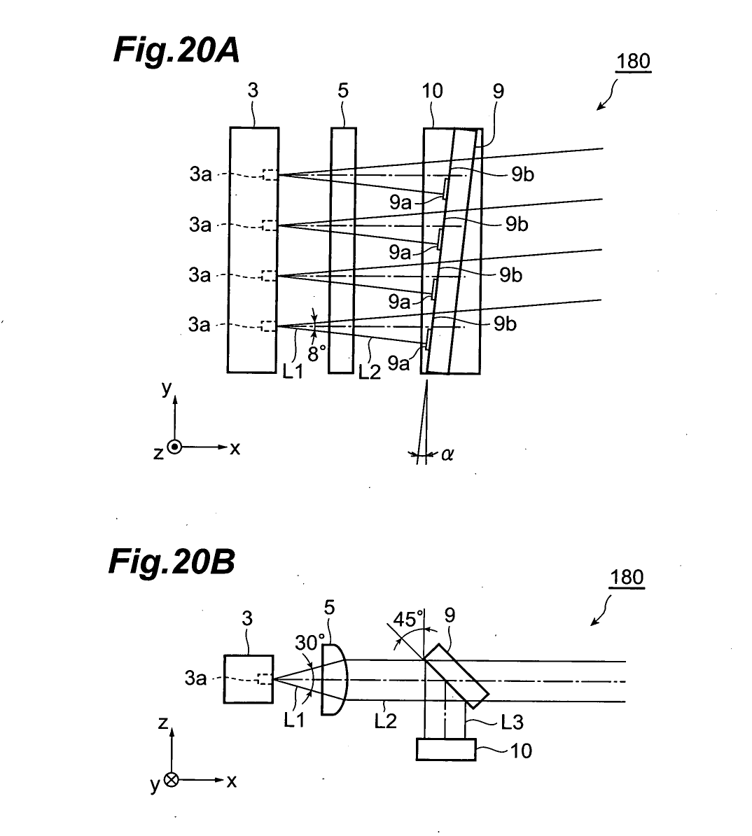

FIG. 20A is a plan view (viewed in the z-axis direction) showing the configuration of a ninth embodiment of a semiconductor laser device according to the present invention, while FIG. 20B is a side elevational view (viewed in the y-axis direction) thereof. The semiconductor laser device 180 according to the ninth embodiment comprises a semiconductor laser array 3, a collimator lens 5, an optical element 9, and a wavelength selecting element 10, as is the case with the semiconductor laser device 130 according to the fourth embodiment (FIGS. 14A and 14B).

The semiconductor laser device 180 according to the ninth embodiment, however, differs from the semiconductor laser device 130 according to the fourth embodiment (FIGS. 14A and 14B) in that the optical element 9 is inclined by about 45° with respect to a plane perpendicular to the optical axis of beams emitted from the semiconductor laser array 3, and that the wavelength selecting element 10 is arranged in a position where beam reflected at the optical element 9 reaches. Except for the difference, the configuration of the semiconductor laser device 160 is the same as that of the semiconductor laser devices 130 to 170 according to the fourth to eighth embodiments, and the descriptions will be omitted.

The optical element 9 in the ninth embodiment has the same configuration as in the first embodiment (FIG. 7). In the optical element 9 are provided, alternately along the y-axis direction, reflecting portions 9a for reflecting beams collimated in the z-axis direction by the collimator lens 5 and transmitting portions 9b for transmitting beams thus collimated. Then, the optical element 9 reflects at least part of beam reflected at each reflecting portion 9a toward the wavelength selecting element 10. The optical element 9 also transmits beam that enters each transmitting portion 9b.

One pair of adjacent reflecting portion 9a and transmitting portion 9b corresponds to one active layer 3a, and the borderline between the reflecting portion 9a and the transmitting portion 9b is parallel to the z-axis direction and exists within the cross-section of each beam reaching the optical element 9 from the collimator lens 5. Therefore, the reflecting portions 9a, which are inclined by 45° with respect to a plane perpendicular to the optical axis of each beam, reflect a partial cross-sectional portion of each beam reaching the optical element 9 from the collimator lens 5 toward the wavelength selecting element 10. Meanwhile, the transmitting portions 9b transmit a cross-sectional portion entering each transmitting portion 9b of each beam reaching the optical element 9 from the collimator lens 5.

The wavelength selecting element 10 in the ninth embodiment reflects each beam reflected at each reflecting portion 9a of the optical element 9 again toward the reflecting portion 9a. In this case, beam reflected at the wavelength selecting element 10 is fedback to the active layer that has emitted the beam via the reflecting portion 9a of the optical element 9.

In the semiconductor laser device 180 according to the ninth embodiment having such a structure, beams emitted from the active layers 3a of the semiconductor laser array 3, which spread in the z-axis direction from the active layers 3a, are refracted through the collimator lens 5 to be in approximately parallel in the z-axis direction to enter the optical element 9. In the optical element 9 are provided reflecting portions 9a for reflecting each beam and transmitting portions 9b for transmitting each beam. At least part of beam reflected at each reflecting portion 9a of the optical element 9 is reflected at the wavelength selecting element 10 again toward the reflecting portion 9a, and then is fedback to the active layer 3a that has emitted the beam via the reflecting portion 9a. Also, beam that transmits through each transmitting portion 9b of the optical element 9 is emitted outside. The arrangement above forms an external resonator between the wavelength selecting element 10 and the active layers 3a, and causes stimulated emission in active layers 3a positioned within the resonator to achieve laser oscillation. Meanwhile, beam that transmits through each transmitting portion 9b of the optical element 9 is emitted outside as output beam of the semiconductor laser device 180. In accordance with the semiconductor laser device 180, it is also possible to reduce the spread angle and the spectrum width of the final output.

### Tenth Embodiment

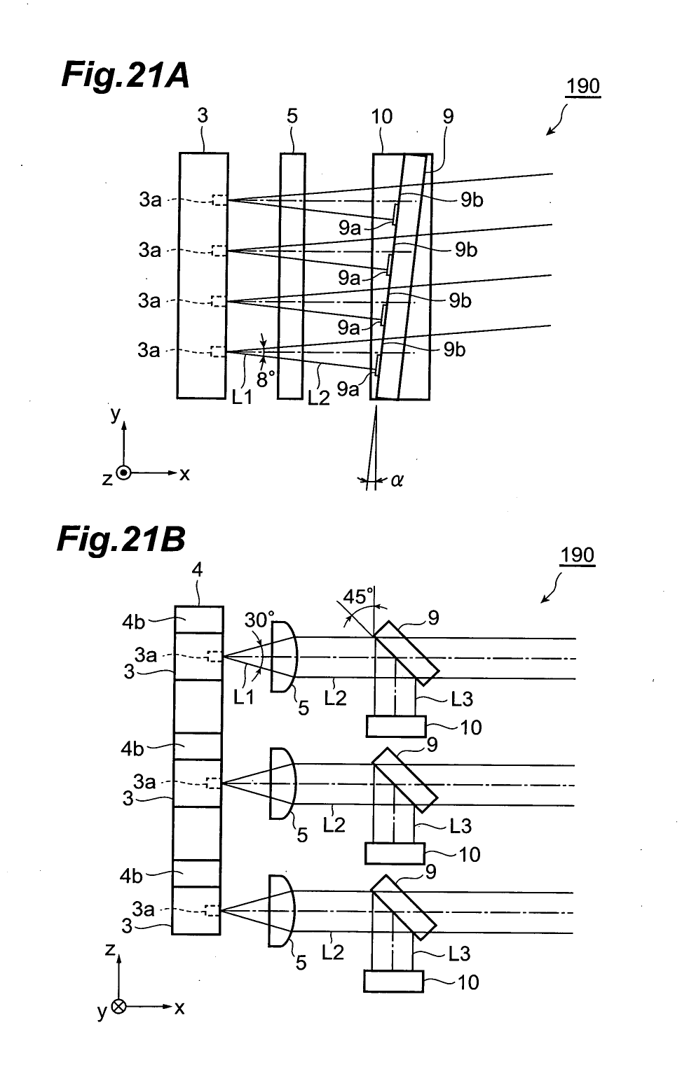

FIG. 21A is a plan view (viewed in the z-axis direction) showing the configuration of a tenth embodiment of a semiconductor laser device according to the present invention, while FIG. 21B is a side elevational view (viewed in the y-axis direction) thereof. The semiconductor laser device 190 according to the tenth embodiment comprises a semiconductor laser array stack 4, a collimator lens 5, an optical element 9, and a wavelength selecting element 10.

The semiconductor laser device 190 according to the tenth embodiment differs from the semiconductor laser device 180 according to the ninth embodiment (FIGS. 20A and 21B) in that the semiconductor laser array stack 4 including plural semiconductor laser arrays 3 is provided. Except for the difference, the configuration of the semiconductor laser device 190 is the same as that of the semiconductor laser device 180 according to the ninth embodiment, and the descriptions will be omitted.

The semiconductor laser array stack 4 has the same configuration as that of the semiconductor laser array stack 4 applied to the second embodiment (FIG. 11). As shown in FIG. 11, the semiconductor laser array stack 4 has a structure in which plural semiconductor laser arrays 3 and plural heat sinks 4h are arranged alternately along the z-axis direction. The heat sinks 4h cool the semiconductor laser arrays 3. Also, the heat sinks 4h each have a cooling channel formed by combining tabular members comprised of copper. Cooling water circulates in the cooling channel.

Each semiconductor laser array 3 has the same configuration as that of the semiconductor laser array 3 in the first embodiment (FIGS. 3, 4A and 4B). Each collimator lens 5 also has the same configuration as that in the first embodiment (FIG. 6). Each optical element 9 has the same configuration as that in the third embodiment (FIG. 7). Further, the wavelength selecting element 10 has approximately the same configuration as that in the fourth embodiment (FIG. 15). The semiconductor laser array 3, collimator lens 5, wavelength selecting element 10, and optical element 9 are arranged in the same manner as in the ninth embodiment.

In the semiconductor laser device 190 according to the tenth embodiment, the resonance of beam generated in the active layers 3a of the semiconductor laser arrays 3 in the resonant optical path causes the spatial transverse mode to be brought close to a single mode, and the closeness of the spatial transverse mode to a single mode allows laser beams having a small spread angle to be output outside via the transmitting portions 9b of the optical element 9. Therefore, in accordance with the semiconductor laser device 190, it is possible to reduce the spread angle of the final output.

### Eleventh Embodiment

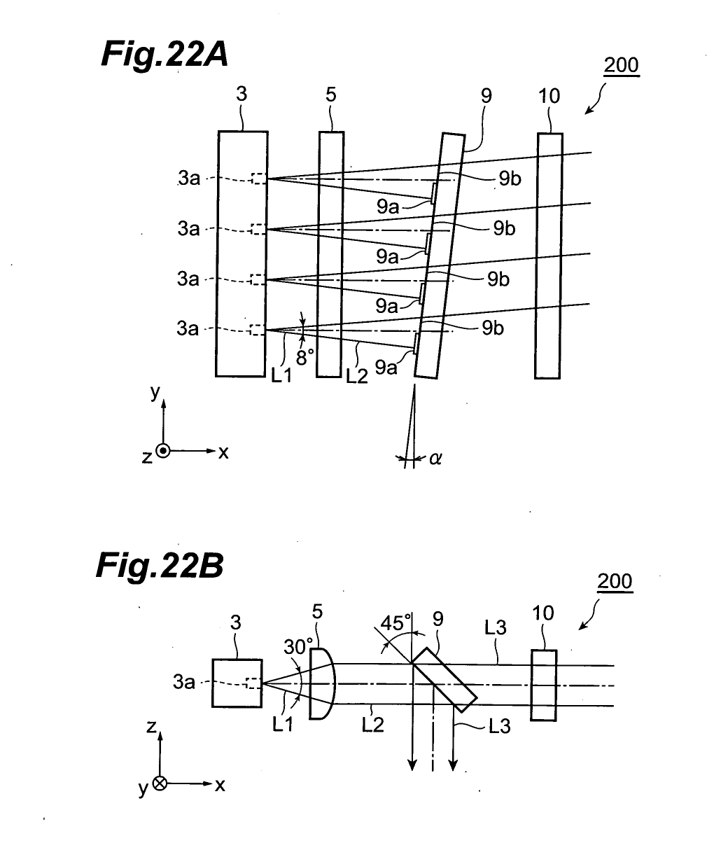

FIG. 22A is a plan view (viewed in the z-axis direction) showing the configuration of an eleventh embodiment of a semiconductor laser device according to the present invention, while FIG. 22B is a side elevational view (viewed in the y-axis direction) thereof. The semiconductor laser device 200 according to the eleventh embodiment comprises a semiconductor laser array 3, a collimator lens 5, an optical element 9, and a wavelength selecting element 10, as is the case with the semiconductor laser device 180 according to the ninth embodiment (FIGS. 20A and 20B).

The semiconductor laser device 200 according to the eleventh embodiment, however, differs from the semiconductor laser device 180 according to the ninth embodiment (FIGS. 20A and 20B) in that the wavelength selecting element 10 is arranged in a position where beam that transmits through each transmitting portion 9b of the optical element 9, and that the wavelength selecting element 10 is arranged in a position where beam reflected at the optical element 9 reaches. Except for the difference, the configuration of the semiconductor laser device 160 is the same as that of the semiconductor laser devices 130 to 170 according to the fourth to eighth embodiments, and the descriptions will be omitted.

The optical element 9 in the eleventh embodiment has the same configuration as in the first embodiment (FIG. 7). In the optical element 9 are provided, alternately along the y-axis direction, reflecting portions 9a for reflecting beams collimated in the z-axis direction by the collimator lens 5 and transmitting portions 9b for transmitting beams thus collimated. Then, the optical element 9 reflects at least part of beam reflected at each reflecting portion 9a toward the outside. The optical element 9 also transmits beam that enters each transmitting portion 9b toward the wavelength selecting element 10.

One pair of adjacent reflecting portion 9a and transmitting portion 9b corresponds to one active layer 3a, and the borderline between the reflecting portion 9a and the transmitting portion 9b is parallel to the z-axis direction and exists within the cross-section of each beam reaching the optical element 9 from the collimator lens 5. Therefore, the reflecting portions 9a, which are inclined by 45° with respect to a plane perpendicular to the optical axis of each beam, reflect a partial cross-sectional portion of each beam reaching the optical element 9 from the collimator lens 5 toward the outside. Meanwhile, the transmitting portions 9b transmit a cross-sectional portion entering each transmitting portion 9b of each beam reaching the optical element 9 from the collimator lens 5 toward the wavelength selecting element 10.

The wavelength selecting element 10 in the eleventh embodiment reflects each beam that transmits through each transmitting portion 9b of the optical element 9 again toward the transmitting portion 9b. In this case, beam reflected at the wavelength selecting element 10 is fedback to the active layer that has emitted the beam via the transmitting portion 9b of the optical element 9.

In the semiconductor laser device 200 according to the eleventh embodiment having such a structure, beams emitted from the active layers 3a of the semiconductor laser array 3, which spread in the z-axis 5 direction from the active layers 3a, are refracted through the collimator lens 5 to be approximately parallel in the z-axis direction to enter the optical element 9. In the optical element 9 are provided reflecting portions 9a for reflecting each beam and transmitting portions 9b for transmitting each beam. At least part of beam that transmits through each transmitting portion 9b of the optical element 9 is reflected at the wavelength selecting element 10 again toward the transmitting portion 9b, and then is fedback to the active layer 3a that has emitted the beam via the transmitting portion 9b. Also, beam reflected at each reflecting portion 9a of the optical element 9 is emitted outside. The arrangement above forms an external resonator between the wavelength selecting element 10 and the active layers 3a, and causes stimulated emission in active layers 3a positioned within the resonator to achieve laser oscillation. Meanwhile, beam reflected at each reflecting portion 9a of the optical element 9 is emitted outside as output beam of the semiconductor laser device 200. In accordance with the semiconductor laser device 200, it is also possible to reduce the spread angle and the spectrum width of the final output.

In addition, the semiconductor laser devices according to the first to eleventh embodiments may further comprise an optical system (e.g., condenser lens) for collecting output beam from the external resonator. For example, in the case an optical fiber is provided as an optical waveguide, arranging the optical system in the optical path between the external resonator and the optical fiber through which output beam from the external resonator propagates allows the output beam from the external resonator to be guided efficiently to the waveguide area of the optical fiber.

In accordance with the foregoing descriptions of the present invention, it is obvious that various modifications may be made for the present invention. Such modifications cannot be considered to depart from the gist and scope of the present invention, and every variation obvious to those skilled in the art is included in the following claims.

### INDUSTRIAL APPLICABILITY

The present invention is suitable for use in semiconductor laser devices for emitting a laser beam having a small spread angle, and further a laser beam having a small spread angle as well as a narrow spectrum width.

1. A semiconductor laser device comprising:
a semiconductor laser array having plural active layers, said active layers extending along a first direction on a predetermined plane and arranged in parallel along a second direction perpendicular to the first direction on the predetermined plane;
a collimator lens for collimating plural beams, respectively emitted from said active layers, in a third direction perpendicular to the predetermined plane; and
an optical element arranged at a position where at least part of each beam emitted from said collimator lens and having a predetermined spread angle in the second direction reaches, in an inclined manner with respect to a plane perpendicular to the first direction, said optical element having, on a plane facing said collimator lens, a reflecting portion for reflecting part of each beam reaching from said collimator lens and a transmitting portion for transmitting the rest of the reaching beam.

2. A semiconductor laser device comprising:
a semiconductor laser array stack in which plural semiconductor laser arrays are stacked in a third direction perpendicular to a predetermined plane, each of said semiconductor laser arrays having plural active layers, said active layers extending along a first direction on the predetermined plane and arranged in parallel along a second direction perpendicular to the first direction on the predetermined plane;
a collimator lens for collimating plural beams, respectively emitted from said active layers, in the third direction perpendicular to the predetermined plane; and
an optical element arranged at a position where at least part of each beam emitted from said collimator lens and having a predetermined spread angle in the second direction reaches, in an inclined manner with respect to a plane perpendicular to the first direction, said optical element having, on a plane facing said collimator lens, a reflecting portion for reflecting part of each beam reaching from said collimator lens and a transmitting portion for transmitting the rest of the reaching beam.

3. A semiconductor laser device according to claim 1, wherein said optical element is arranged in such a manner that part of each beam reaching said reflecting portion from said collimator lens is fedback to said active layers, and constitutes an off-axis external resonator having a resonant optical path deviated from the optical axis of each beam together with said active layers.

4. A semiconductor laser device according to claim 1, further comprising a wavelength selecting element arranged in such a manner that part of each beam emitted from said collimator lens and having a spread angle in the second direction reaches perpendicularly, and constituting an off-axis external resonator having a resonant optical path deviated from the optical axis of each beam together with said optical element, said wavelength selecting element Bragg-reflecting part of beam with a specific wavelength, among the perpendicularly reaching beams, in such a manner as to be fedback to said active layers, while transmitting the rest of the beam with the specific wavelength.

5. A semiconductor laser device according to claim 1, further comprising a wavelength selecting element arranged in such a manner that part of each beam emitted from said collimator lens and having a spread angle in the second direction is reflected diffractively, and constituting an off-axis external resonator having a resonant optical path deviated from the optical axis of each beam together with said optical element, said wavelength selecting element diffractively reflecting diffracted beam with a specific order having a specific wavelength, among diffracted beams, in such a manner as to be fedback to said active layers, while guiding diffracted beam with the specific wavelength having an order other than the specific order outside.

6. A semiconductor laser device according to claim 1, further comprising a wavelength selecting element arranged at a position where part of each beam emitted from said collimator lens and having a spread angle in the second direction reaches after reflection at said reflecting portion of said optical element, and causing the reaching beam to be fedback to said active layers via said reflecting portion, said wavelength selecting element constituting an off-axis external resonator having a resonant optical path deviated from the optical axis of each beam together with said active layers.

7. A semiconductor laser device according to claim 1, further comprising a wavelength selecting element arranged at a position where part of beam transmitting through said transmitting portion of said optical element, among beams emitted from said collimator lens and having a spread angle in the second direction, reaches, and causing the reaching beam to be fedback to said active layers through said transmitting portion, said wavelength selecting element constituting an off-axis external resonator having a resonant optical path deviated from the optical axis of each beam together with said active layers.

8. A semiconductor laser device comprising:
a semiconductor laser array having plural active layers said active layers extending along a first direction on a predetermined plane and arranged in parallel along a second direction perpendicular to the first direction on the predetermined plane;
a collimator lens for collimating plural beams, respectively emitted from said active layers, in a third direction perpendicular to the predetermined plane; and
an optical element arranged at a position where at least part of each beam emitted from said collimator lens and having a predetermined spread angle in the second direction reaches, and constituting an off-axis external resonator having a resonant optical path deviated from the optical axis of each beam together with said active layers, said optical element having, on a plane facing said collimator lens, a reflecting portion for reflecting part of each beam reaching from said collimator lens in such a manner as to be fedback to said active layers and a transmitting portion for transmitting the rest of the reaching beam.

9. A semiconductor laser device comprising:
a semiconductor laser array stack in which plural semiconductor laser arrays are stacked in a third direction perpendicular to a predetermined plane, each of said semiconductor laser arrays having plural active layers, said active layers extending along a first direction on the predetermined plane and arranged in parallel along a second direction perpendicular to the first direction on the predetermined plane;
a collimator lens for collimating plural beams, respectively emitted from said active layers, in the third direction; and
an optical element arranged at a position where at least part of each beam emitted from said collimator lens and having a predetermined spread angle in the second direction reaches, and constituting an off-axis external resonator having a resonant optical path deviated from the optical axis of each beam together with said active layers, said optical element having, on a plane facing said collimator lens, a reflecting portion for reflecting part of each beam reaching from said collimator lens in such a manner as to be fedback to said active layers and a transmitting portion for transmitting the rest of the reaching beam.

10. A semiconductor laser device according to claim 8, wherein said reflecting portion and said transmitting portion of said optical element are arranged alternately along the second direction on a plane facing said collimator lens.

11. A semiconductor laser device according to claim 10, wherein said optical element comprises a tabular substrate comprised of translucent material and having a surface on which said reflecting portion and said transmitting portion are arranged alternately along the second direction.

12. A semiconductor laser device according to claim 11, wherein said tabular substrate of said optical element is arranged in an inclined manner with respect to a plane perpendicular to the optical axis of each beam emitted from said collimator lens and having a predetermined spread angle in the second direction so that at least part of each beam reaching said reflecting portion enters said reflecting portion perpendicularly.

13. A semiconductor laser device according to claim 11, wherein said reflecting portion includes a total reflection film provided on the surface of said tabular substrate.

14. A semiconductor laser device according to claim 11, wherein said reflecting portion includes a diffraction grating provided on the surface of said tabular substrate.

15. A semiconductor laser device according to claim 11, wherein said reflecting portion includes an etalon provided on the surface of said tabular substrate.

16. A semiconductor laser device according to claim 11, wherein said transmitting portion includes a reflection suppressing film provided on the surface of said tabular substrate.

17. A semiconductor laser device comprising:
a semiconductor laser array having plural active layers, said active layers extending along a first direction on a predetermined plane and arranged in parallel along a second direction perpendicular to the first direction on the predetermined plane;
a collimator lens for collimating plural beams, respectively emitted from said active layers, in a third direction perpendicular to the predetermined plane;
an optical element arranged at a position where at least part of each beam emitted from said collimator lens and having a predetermined spread angle in the second direction reaches, said optical element having, on a plane facing said collimator lens, a reflecting portion for reflecting part of each beam reaching from said collimator lens in such a manner as to be fedback to said active layers and a transmitting portion for transmitting the rest of the reaching beam; and
a wavelength selecting element arranged in such a manner that part of each beam emitted from said collimator lens and having a spread angle in the second direction reaches perpendicularly, and constituting an off-axis external resonator having a resonant optical path deviated from the optical axis of each beam together with said optical element, said wavelength selecting element Bragg-reflecting part of beam with a specific wavelength, among the perpendicularly reaching beams, in such a manner as to be fedback to said active layers, while transmitting the rest of the beam with the specific wavelength.

18. A semiconductor laser device comprising:
a semiconductor laser array stack in which plural semiconductor laser arrays are stacked in a third direction perpendicular to a predetermined plane, each of said semiconductor laser arrays having plural active layers, said active layers extending along a first direction on the predetermined plane and arranged in parallel along a second direction perpendicular to the first direction on the predetermined plane;
a collimator lens for collimating plural beams, respectively emitted from said active layers, in the third direction;
an optical element arranged at a position where at least part of each beam emitted from said collimator lens and having a predetermined spread angle in the second direction reaches, said optical element having, on a plane facing said collimator lens, a reflecting portion for reflecting part of each beam reaching from said collimator lens in such a manner as to be fedback to said active layers and a transmitting portion for transmitting the rest of the reaching beam; and
a wavelength selecting element arranged in such a manner that part of each beam emitted from said collimator lens and having a spread angle in the second direction reaches perpendicularly, and constituting an off-axis external resonator having a resonant optical path deviated from the optical axis of each beam together with said optical element, said wavelength selecting element Bragg-reflecting part of beam with a specific wavelength, among the perpendicularly reaching beams, in such a manner as to be fedback to said active layers, while transmitting the rest of the beam with the specific wavelength.

19. A semiconductor laser device comprising:
a semiconductor laser array having plural active layers, said active layers extending along a first direction on a predetermined plane and arranged in parallel along a second direction perpendicular to the first direction on the predetermined plane;
a collimator lens for collimating plural beams, respectively emitted from said active layers, in a third direction perpendicular to the predetermined plane;
an optical element arranged at a position where at least part of each beam emitted from said collimator lens and having a predetermined spread angle in the second direction reaches, said optical element having, on a plane facing said collimator lens a reflecting portion for reflecting part of each beam reaching from said collimator lens in such a manner as to be fedback to said active layers and a transmitting portion for transmitting the rest of the reaching beam; and
a wavelength selecting element arranged in such a manner that part of each beam emitted from said collimator lens and having a spread angle in the second direction is reflected diffractively, and constituting an off-axis external resonator having a resonant optical path deviated from the optical axis of each beam together with said optical element, said wavelength selecting element diffractively reflecting diffracted beam with a specific wavelength having a specific order, among diffracted beams, in such a manner as to be fedback to said active layers, while guiding the diffracted beam with the specific wavelength having an order other than the specific order outside.

20. A semiconductor laser device comprising:
a semiconductor laser array stack in which plural semiconductor laser arrays are stacked in a third direction perpendicular to a predetermined plane, each of said semiconductor laser arrays having plural active layers, said active layers extending along a first direction on the predetermined plane and arranged in parallel along a second direction perpendicular to the first direction on the predetermined plane;
a collimator lens for collimating plural beams, respectively emitted from said active layers, in the third direction;
an optical element arranged at a position where at least part of each beam emitted from said collimator lens and having a predetermined spread angle in the second direction reaches, said optical element having, on a plane facing said collimator lens, a reflecting portion for reflecting part of each beam reaching from said collimator lens in such a manner as to be fedback to said active layers and a transmitting portion for transmitting the rest of the reaching beam; and
a wavelength selecting element arranged in such a manner that part of each beam emitted from said collimator lens and having a spread angle in the second direction is reflected diffractively, and constituting an off-axis external resonator having a resonant optical path deviated from the optical axis of each beam together with said optical element, said wavelength selecting element diffractively reflecting diffracted beam with a specific wavelength having a specific order, among diffracted beams, in such a manner as to be fedback to said active layers, while guiding the diffracted beam with the specific wavelength having an order other than the specific order outside.

21. A semiconductor laser device according to claim 17, wherein said optical element is arranged between said collimator lens and said wavelength selecting element, and
wherein said wavelength selecting element is arranged in such a manner as to receive, among beams emitted from said collimator lens and having a predetermined spread angle in the second direction, beam transmitting through said transmitting portion of said optical element.

22. A semiconductor laser device according to claim 17, wherein said wavelength selecting element is arranged between said collimator lens and said optical element in such a manner as to receive, among beams emitted from said collimator lens and having a predetermined spread angle in the second direction, beam that travels toward said transmitting portion of said optical element.

23. A semiconductor laser device according to claim 17, wherein said optical element comprises a tabular substrate comprised of translucent material and having a surface on which said reflecting portion and said transmitting portion are formed.

24. A semiconductor laser device according to claim 17, wherein said reflecting portion and said transmitting portion of said optical element are arranged alternately along the second direction, on the surface of said tabular substrate.

25. A semiconductor laser device according to claim 17, wherein said tabular substrate of said optical element is arranged in an inclined manner with respect to a plane perpendicular to the optical axis of each beam emitted from said collimator lens and having a predetermined spread angle in the second direction so that at least part of each beam reaching said reflecting portion enters said reflecting portion perpendicularly.

26. A semiconductor laser device comprising:
a semiconductor laser array having plural active layers, said active layers extending along a first direction on a predetermined plane and arranged in parallel along a second direction perpendicular to the first direction on the predetermined plane;
a collimator lens for collimating plural beams, respectively emitted from said active layers, in a third direction perpendicular to the predetermined plane;
an optical element arranged at a position where at least part of each beam emitted from said collimator lens and having a predetermined spread angle in the second direction reaches, in an inclined manner with respect to a plane perpendicular to the first direction, said optical element having, on a plane facing said collimator lens, a reflecting portion for reflecting part of each beam reaching from said collimator lens and a transmitting portion for transmitting the rest of the reaching beam; and
a wavelength selecting element arranged at a position where part of each beam emitted from said collimator lens and having a spread angle in the second direction reaches via said optical element, and causing the reaching beam to be fedback to said active layers via said optical element, said wavelength selecting element constituting an off-axis external resonator having a resonant optical path deviated from the optical axis of each beam together with said active layers.

27. A semiconductor laser device according to claim 26, wherein said wavelength selecting element is arranged at a position where part of beam transmitting through said reflecting portion of said optical element, among beams emitted from said collimator lens and having a spread angle in the second direction, reaches, and causes the reaching beam to be fedback to said active layers via the reflecting portion.

28. A semiconductor laser device according to claim 26, wherein said wavelength selecting element is arranged at a position where part of beam transmitting through said reflecting portion of said optical element, among beams emitted from said collimator lens and having a spread angle in the second direction, reaches, and causes the reaching beam to be fedback to said active layers via said transmitting portion.

29. A semiconductor laser device according to claim 2, wherein said optical element is arranged in such a manner that part of each beam reaching said reflecting portion from said collimator lens is fedback to said active layers, and constitutes an off-axis external resonator having a resonant optical path deviated from the optical axis of each beam together with said active layers.

30. A semiconductor laser device according to claim 2, further comprising a wavelength selecting element arranged in such a manner that part of each beam emitted from said collimator lens and having a spread angle in the second direction reaches perpendicularly, and constituting an off-axis external resonator having a resonant optical path deviated from the optical axis of each beam together with said optical element, said wavelength selecting element Bragg-reflecting part of beam with a specific wavelength, among the perpendicularly reaching beams, in such a manner as to be fedback to said active layers, while transmitting the rest of the beam with the specific wavelength.

31. A semiconductor laser device according to claim 2, further comprising a wavelength selecting element arranged in such a manner that part of each beam emitted from said collimator lens and having a spread angle in the second direction is reflected diffractively, and constituting an off-axis external resonator having a resonant optical path deviated from the optical axis of each beam together with said optical element, said wavelength selecting element diffractively reflecting diffracted beam with a specific order having a specific wavelength, among diffracted beams, in such a manner as to be fedback to said active layers, while guiding diffracted beam with the specific wavelength having an order other than the specific order outside.

32. A semiconductor laser device according to claim 2, further comprising a wavelength selecting element arranged at a position where part of each beam emitted from said collimator lens and having a spread angle in the second direction reaches after reflection at said reflecting portion of said optical element, and causing the reaching beam to be fedback to said active layers via said reflecting portion, said wavelength selecting element constituting an off-axis external resonator having a resonant optical path deviated from the optical axis of each beam together with said active layers.

33. A semiconductor laser device according to claim 2, further comprising a wavelength selecting element arranged at a position where part of beam transmitting through said transmitting portion of said optical element, among beams emitted from said collimator lens and having a spread angle in the second direction, reaches, and causing the reaching beam to be fedback to said active layers through said transmitting portion, said wavelength selecting element constituting an off-axis external resonator having a resonant optical path deviated from the optical axis of each beam together with said active layers.

34. A semiconductor laser device according to claim 9, wherein said reflecting portion and said transmitting portion of said optical element are arranged alternately along the second direction on a plane facing said collimator lens.

35. A semiconductor laser device according to claim 34, wherein said optical element comprises a tabular substrate comprised of translucent material and having a surface on which said reflecting portion and said transmitting portion are arranged alternately along the second direction.

36. A semiconductor laser device according to claim 35, wherein said tabular substrate of said optical element is arranged in an inclined manner with respect to a plane perpendicular to the optical axis of each beam emitted from said collimator lens and having a predetermined spread angle in the second direction so that at least part of each beam reaching said reflecting portion enters said reflecting portion perpendicularly.

37. A semiconductor laser device according to claim 35, wherein said reflecting portion includes a total reflection film provided on the surface of said tabular substrate.

38. A semiconductor laser device according to claim 35, wherein said reflecting portion includes a diffraction grating provided on the surface of said tabular substrate.

39. A semiconductor laser device according to claim 35, wherein said reflecting portion includes an etalon provided on the surface of said tabular substrate.

40. A semiconductor laser device according to claim 35, wherein said transmitting portion includes a reflection suppressing film provided on the surface of said tabular substrate.

41. A semiconductor laser device according to claim 18, wherein said optical element is arranged between said collimator lens and said wavelength selecting element, and
wherein said wavelength selecting element is arranged in such a manner as to receive, among beams emitted from said collimator lens and having a predetermined spread angle in the second direction, beam transmitting through said transmitting portion of said optical element.

42. A semiconductor laser device according to claim 18, wherein said wavelength selecting element is arranged between said collimator lens and said optical element in such a manner as to receive, among beams emitted from said collimator lens and having a predetermined spread angle in the second direction, beam that travels toward said transmitting portion of said optical element.

43. A semiconductor laser device according to claim 18, wherein said optical element comprises a tabular substrate comprised of translucent material and having a surface on which said reflecting portion and said transmitting portion are formed.

44. A semiconductor laser device according to claim 18, wherein said reflecting portion and said transmitting portion of said optical element are arranged alternately along the second direction, on the surface of said tabular substrate.

45. A semiconductor laser device according to claim 18, wherein said tabular substrate of said optical element is arranged in an inclined manner with respect to a plane perpendicular to the optical axis of each beam emitted from said collimator lens and having a predetermined spread angle in the second direction so that at least part of each beam reaching said reflecting portion enters said reflecting portion perpendicularly.

46. A semiconductor laser device according to claim 19, wherein said optical element is arranged between said collimator lens and said wavelength selecting element, and
wherein said wavelength selecting element is arranged in such a manner as to receive, among beams emitted from said collimator lens and having a predetermined spread angle in the second direction, beam transmitting through said transmitting portion of said optical element.

47. A semiconductor laser device according to claim 19, wherein said optical element comprises a tabular substrate comprised of translucent material and having a surface on which said reflecting portion and said transmitting portion are formed.

48. A semiconductor laser device according to claim 19, wherein said reflecting portion and said transmitting portion of said optical element are arranged alternately along the second direction, on the surface of said tabular substrate.

49. A semiconductor laser device according to claim 19, wherein said tabular substrate of said optical element is arranged in an inclined manner with respect to a plane perpendicular to the optical axis of each beam emitted from said collimator lens and having a predetermined spread angle in the second direction so that at least part of each beam reaching said reflecting portion enters said reflecting portion perpendicularly.

50. A semiconductor laser device according to claim 20, wherein said optical element is arranged between said collimator lens and said wavelength selecting element, and
wherein said wavelength selecting element is arranged in such a manner as to receive, among beams emitted from said collimator lens and having a predetermined spread angle in the second direction, beam transmitting through said transmitting portion of said optical element.

51. A semiconductor laser device according to claim 20, wherein said optical element comprises a tabular substrate comprised of translucent material and having a surface on which said reflecting portion and said transmitting portion are formed.

52. A semiconductor laser device according to claim 20, wherein said reflecting portion and said transmitting portion of said optical element are arranged alternately along the second direction, on the surface of said tabular substrate.

53. A semiconductor laser device according to claim 20, wherein said tabular substrate of said optical element is arranged in an inclined manner with respect to a plane perpendicular to the optical axis of each beam emitted from said collimator lens and having a predetermined spread angle in the second direction so that at least part of each beam reaching said reflecting portion enters said reflecting portion perpendicularly.
